(19) United States
(12) Patent Application Publication
(10) Pub. No.: US 2009/0108706 A1
(43) Pub. Date: Apr. 30, 2009

(54) FERROELECTRIC OXIDE, PROCESS FOR PRODUCING THE SAME, PIEZOELECTRIC BODY, AND PIEZOELECTRIC DEVICE

(75) Inventors: Yukihiro OKUNO, Minamiashigara-shi (JP); Yukio Sakashita, Kanagawa-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/256,900

(22) Filed: Oct. 23, 2008

(30) Foreign Application Priority Data
Oct. 24, 2007 (JP) 2007-276480
May 22, 2008 (JP) 2008-134664

(51) Int. Cl. H01L 41/18; H01L 41/04

(52) U.S. Cl. 310/311; 252/62.9 R

(57) ABSTRACT

A composition of a ferroelectric oxide represented by General Formula (a) is adjusted such that the most stable crystal structures X and Y of ACO₃ and BDO₃, respectively, have different symmetry characteristics and different directions of polarization, and such that Formula (1) is satisfied:

(Aₓ,B₁₋ₓ)(C_{y},D_{1-y})O₃ (a)

|E(X)−E(Y)|≦E·PV (1)

wherein each of A to D represents at least one kind of a metal element, E(X) and E(Y) represent the energy at the time of the crystal structures X and Y, respectively, P represents the spontaneous polarization density vector, E represents the actuating electric field vector, and V represents the volume of the fundamental lattice.

### BACKGROUND OF THE INVENTION

1. Field of the Invention

This invention relates to a ferroelectric oxide, and a process for producing the ferroelectric oxide. This invention also relates to a ferroelectric composition containing the ferroelectric oxide. This invention further relates to a piezoelectric body containing the ferroelectric oxide, and a piezoelectric device provided with the piezoelectric body.

2. Description of the Related Art

Piezoelectric devices provided with a piezoelectric body, which has piezoelectric characteristics such that the piezoelectric body expands and contracts in accordance with an increase and a decrease in electric field applied across the piezoelectric body, and electrodes for applying the electric field across the piezoelectric body have heretofore been used as actuators to be loaded on ink jet type recording heads, and the like. As piezoelectric body materials, there have heretofore been known perovskite type oxides, such as lead zirconate titanate (PZT). PZT is a ferroelectric substance, which has spontaneous polarization characteristics at the time free from electric field application.

PZT is a solid solution of PbTiO₃ (PT) and PbZrO₃ (PZ). FIG. 8 is a phase chart of PZT, wherein a Zr/Ti proportion is set at various different values. FIG. 8 is the phase chart described in “LANDOLT-BORNSTEIN, Numerical Data and Functional Relationships in Science and Technology, New Series,” Group III: Crystal and Solid State Physics, Vol. 16, Editors: K. H. Hellwege and A. M. Hellwege, Springer-Verlag, 1981, p. 426, FIG. 728. In FIG. 8, FT represents a tetragonal phase, and F_{R} represents a rhombohedral phase.

As for PZT, in cases where the proportion of Ti becomes high, the crystal phase is apt to become the tetragonal phase. Also, in cases where the proportion of Zr becomes high, the crystal phase is apt to become the rhombohedral phase. In cases where Ti and Zr are contained in approximately equimolar quantities, the morphotropic phase boundary (MPB) composition is obtained. As for PZT, it has been theorized that a composition of, for example, a molar ratio of Zr/Ti=52/48, which is the composition in the vicinity of the MPB, is appropriate. It has also been theorized that, in the cases of the compositions at the MPB and in the vicinity of the MPB, the crystal structure becomes unstable, and the highest piezoelectric performance is obtained. It has been reported that, in the cases of the compositions at the MPB and in the vicinity of the MPB, a two-phase mixed crystal structure comprising the tetragonal phase and the rhombohedral phase is obtained. The crystal structure is changed by phase transition due to electric field application. As a result, the direction of polarization rotates, and high piezoelectric performance is obtained.

With the conventional piezoelectric devices, ordinarily, an electric field is applied in a direction matched with a spontaneous polarization axis of the ferroelectric substance, and the piezoelectric effect extending in the direction of the spontaneous polarization axis is thereby utilized. Specifically, heretofore, it has been regarded to be important that material design be made such that the direction of the electric field application and the direction of the spontaneous polarization axis may coincide with each other (i.e., direction of spontaneous polarization axis=direction of electric field application). However, in cases where the aforesaid piezoelectric effect of the ferroelectric substances is merely utilized, the quantity of strain displacement of the piezoelectric device is limited. Therefore, nowadays there is a strong demand for piezoelectric devices having enhanced strain displacement quantity.

In view of the above circumstances, the inventors have proposed a piezoelectric device, comprising: a piezoelectric body containing a first ferroelectric phase, which has crystal orientational characteristics, and which has characteristics such that, with electric field application, at least a part of the first ferroelectric phase undergoes phase transition to a second ferroelectric phase of a crystal system different from the crystal system of the first ferroelectric phase. (Reference may be made to International Patent Publication No. WO2007/034903.)

With the piezoelectric device described in International Patent Publication No. WO2007/034903, the volume change is obtained due to the change of the crystal structure accompanying the phase transition of the first ferroelectric phase. Also, the piezoelectric body contains the ferroelectric substance at both the stage before the phase transition occurs and the stage after the phase transition has occurred. Therefore, the piezoelectric effect of the ferroelectric substance is obtained at both the stage before the phase transition occurs and the stage after the phase transition has occurred. Accordingly, a large quantity of the strain displacement is obtained.

In International Patent Publication No. WO2007/034903, the inventors have indicated that the direction of the spontaneous polarization axis of the first ferroelectric phase at the stage before the phase transition occurs should preferably be different from the direction of the electric field application. Also, the inventors have indicated that the direction of the electric field application should particularly preferably approximately coincide with the direction of the spontaneous polarization axis of the second ferroelectric phase at the stage after the phase transition has occurred. Further, the inventors have indicated that, in such cases, an enhanced strain displacement quantity is obtained due to an “engineered domain effect,” and the like.

Recently, an increasing interest has been taken in environmental load, and there is a strong demand for the use of non-lead type piezoelectric body materials. As a non-lead perovskite type oxide, barium titanate (BaTiO₃) is well known. However, in comparison with the piezoelectric characteristics of PZT, the piezoelectric characteristics of the non-lead type piezoelectric bodies, such as barium titanate, are not yet sufficiently high. Therefore, various material systems have heretofore been studied as the non-lead perovskite type oxides having high piezoelectric characteristics.

For example, in “Theoretical Prediction of New High-Performance Lead-Free Piezoelectrics”, P. Baettig et al., Chem. Mater., Vol. 17, pp. 1376-1380, 2005, it is described that the most stable crystal structures of BiAlO₃ and BiGaO₃ and polarization intensities in the aforesaid crystal structures are obtained by calculations with a density functional theory, and that Bi(Al,Ga)O₃ will be capable of constituting a non-lead type piezoelectric body which has piezoelectric characteristics as good as the piezoelectric characteristics of PZT.

As described above, with the piezoelectric device proposed in International Patent Publication No. WO2007/034903, a large quantity of the strain displacement is obtained, and therefore high piezoelectric characteristics are obtained. Accordingly, if the piezoelectric device proposed in International Patent Publication No. WO2007/034903 is capable of being constituted by use of the non-lead type piezoelectric body, it will be possible for the non-lead type piezoelectric device having good piezoelectric characteristics to be formed.

Therefore, if a material and a composition of a piezoelectric body, which are applicable to the piezoelectric device proposed in International Patent Publication No. WO2007/034903, are capable of being determined by a simple method, it will be possible for the non-lead type piezoelectric body and the non-lead type piezoelectric device having sufficient piezoelectric characteristics to be formed.

In the aforesaid “Theoretical Prediction of New High-Performance Lead-Free Piezoelectrics”, P. Baettig et al., Chem. Mater., Vol. 17, pp. 1376-1380, 2005, it is described that the crystal structures of the two kinds of the perovskite type oxides, which are to form a solid solution together, and the polarization intensities in the aforesaid crystal structures are obtained by calculations, and that Bi(Al,Ga)O₃ will be capable of constituting the non-lead type piezoelectric body which has piezoelectric characteristics as good as the piezoelectric characteristics of PZT. However, the studies made in the aforesaid literature do not extend beyond the material search. In the aforesaid literature, nothing is described with respect to a design of an appropriate composition, and a comparison and a study are not made with respect to the rhombohedral system and the tetragonal system.

### SUMMARY OF THE INVENTION

The primary object of the present invention is to provide a novel material design idea for a non-lead perovskite type oxide which has good piezoelectric performance (good ferroelectric performance).

The specific object of the present invention is to provide a material design idea which is appropriate for a system of electric field-induced phase transition having been proposed by the inventors in International Patent Publication No. WO2007/034903.

Another object of the present invention is to provide a process for producing a perovskite type oxide, wherein the perovskite type oxide is produced in accordance with the aforesaid material design idea.

A further object of the present invention is to provide a perovskite type oxide, which has been designed in accordance with the aforesaid material design idea.

A still further object of the present invention is to provide a ferroelectric composition containing the perovskite type oxide.

Another object of the present invention is to provide a piezoelectric body containing the perovskite type oxide.

A further object of the present invention is to provide a piezoelectric device provided with the piezoelectric body.

The present invention principally concerns the non-lead perovskite type oxide. However, the present invention is also applicable to a lead perovskite type oxide, and a ferroelectric oxide which is other than the perovskite type oxide.

The present invention provides a process for producing a ferroelectric oxide having a composition that is represented by General Formula (a) shown below,

wherein the composition of the ferroelectric oxide is adjusted such that the most stable crystal structure X of the ferroelectric oxide that is represented by ACO₃ and the most stable crystal structure Y of the ferroelectric oxide that is represented by BDO₃ have different symmetry characteristics and different directions of polarization, and such that Formula (1) shown below is satisfied, and

the ferroelectric oxide having the thus adjusted composition is produced:

(Aₓ,B₁₋ₓ)(C_{y},D_{1-y})O₃ (a)

wherein x represents a number satisfying the condition of 0≦x≦1,

y represents a number satisfying the condition of 0≦y≦1,

each of A and B represents the A site element,

each of C and D represents the B site element,

O represents an oxygen atom,

each of A, B, C and D represents at least one kind of a metal element,

A and B may be of different compositions or may be of a common composition, with the proviso that, in cases where A and B are of the common composition, C and D are of different compositions, and

C and D may be of different compositions or may be of a common composition, with the proviso that, in cases where C and D are of the common composition, A and B are of different compositions,

|E(X)−E(Y)|≦E·PV (1)

wherein E(X) represents the energy of the ferroelectric oxide that is represented by General Formula (a) shown above at the time of the crystal structure X,

E(Y) represents the energy of the ferroelectric oxide that is represented by General Formula (a) shown above at the time of the crystal structure Y,

P represents the spontaneous polarization density vector at a stage before an electric field is applied,

E represents the actuating electric field vector,

V represents the volume of the fundamental lattice, and

E·P represents the inner product of E and P.

The process for producing a ferroelectric oxide in accordance with the present invention should preferably be modified such that the composition is adjusted such that Formula (2) or Formula (3) shown below is satisfied:

|Px/Py|>1.1 (2)

|Py/Px|>1.1 (3),

wherein Px represents the spontaneous polarization density of the ferroelectric oxide that is represented by General Formula (a) at the time of the crystal structure X, and

Py represents the spontaneous polarization density of the ferroelectric oxide that is represented by General Formula (a) at the time of the crystal structure Y.

Also, in cases where the crystal structure X or the crystal structure Y is of a tetragonal system (including a pseudo tetragonal system), the process for producing a ferroelectric oxide in accordance with the present invention should preferably be modified such that the composition is adjusted such that Formula (4) shown below is satisfied:

c/a≧1.008 (4)

wherein c represents the c-axis length in the crystal structure X or the crystal structure Y which is of the tetragonal system, and

a represents the a-axis length in the crystal structure X or the crystal structure Y which is of the tetragonal system.

The present invention also provides a ferroelectric oxide, having a composition that is represented by General Formula (a) shown below (with the proviso that Pb(Zr,Ti)O₃ is excluded),

wherein the ferroelectric oxide has the composition such that the most stable crystal structure X of the ferroelectric oxide that is represented by ACO₃ and the most stable crystal structure Y of the ferroelectric oxide that is represented by BDO₃ have different symmetry characteristics and different directions of polarization, and such that Formula (1) shown below is satisfied:

(Aₓ,B₁₋ₓ)(C_{y},D_{1-y})O₃ (a)

wherein x represents a number satisfying the condition of 0≦x≦1,

y represents a number satisfying the condition of 0≦y≦1,

each of A and B represents the A site element,

each of C and D represents the B site element,

O represents an oxygen atom,

each of A, B, C and D represents at least one kind of a metal element,

A and B may be of different compositions or may be of a common composition, with the proviso that, in cases where A and B are of the common composition, C and D are of different compositions, and

C and D may be of different compositions or may be of a common composition, with the proviso that, in cases where C and D are of the common composition, A and B are of different compositions,

|E(X)−E(Y)|≦E·PV (1)

wherein E(X) represents the energy of the ferroelectric oxide that is represented by General Formula (a) shown above at the time of the crystal structure X,

E(Y) represents the energy of the ferroelectric oxide that is represented by General Formula (a) shown above at the time of the crystal structure Y,

P represents the spontaneous polarization density vector at a stage before an electric field is applied,

E represents the actuating electric field vector,

V represents the volume of the fundamental lattice, and

E·P represents the inner product of E and P.

The ferroelectric oxide in accordance with the present invention should preferably be modified such that the ferroelectric oxide has the composition such that Formula (2) or Formula (3) shown below is satisfied:

|Px/Py|>1.1 (2)

|Py/Px|>1.1 (3),

wherein Px represents the spontaneous polarization density of the ferroelectric oxide that is represented by General Formula (a) at the time of the crystal structure X, and

Py represents the spontaneous polarization density of the ferroelectric oxide that is represented by General Formula (a) at the time of the crystal structure Y.

Also, in cases where the crystal structure X or the crystal structure Y is of the tetragonal system, the ferroelectric oxide in accordance with the present invention should preferably be modified such that the ferroelectric oxide has the composition such that Formula (4) shown below is satisfied:

c/a≧1.008 (4)

wherein c represents the c-axis length in the crystal structure X or the crystal structure Y which is of the tetragonal system, and

a represents the a-axis length in the crystal structure X or the crystal structure Y which is of the tetragonal system.

The spontaneous polarization density vector P and the volume V of the fundamental lattice may be those of the ferroelectric oxide that is represented by General Formula (a) at the time of the crystal structure X. Alternatively, the spontaneous polarization density vector P and the volume V of the fundamental lattice may be those of the ferroelectric oxide that is represented by General Formula (a) at the time of the crystal structure Y.

With the process for producing a ferroelectric oxide in accordance with the present invention, with respect to the ferroelectric oxide that is represented by General Formula (a) shown above, each of the most stable crystal structure X of the ferroelectric oxide that is represented by ACO₃ and the most stable crystal structure Y of the ferroelectric oxide that is represented by BDO₃ is obtained theoretically by calculations. Also, a combination of the crystal structure X and the crystal structure Y is selected such that the crystal structure X and the crystal structure Y have different symmetry characteristics and different directions of polarization. Further, the composition of General Formula (a) shown above is adjusted such that the relationship defined above is obtained. The ferroelectric oxide that satisfies Formula (1) has the composition in the vicinity of the MPB composition and contains the crystal structure X and the crystal structure Y, which are mixed together. It has been known that, ordinarily, in the cases of a thin film, the composition in the vicinity of the MPB composition of the ferroelectric oxide extends over the range of approximately ±8% with respect to the cases of a bulk form. (Reference may be made to, for example, “Dependence of electrical properties of epitaxial Pb(Zr,Ti)O₃ thick films of crystal orientation and Zr/(Zr+Ti) ratio”, S. Yokoyama et al., Journal of Applied Physics, Vol. 98, 094106, 2005, FIG. 3.) Therefore, as for the values of x and y adjusted in accordance with the present invention, in the cases of the thin film, the values of xₘᵢₙ and yₘᵢₙ, which are the minimum values of x and y that satisfy Formula (1), and the values of xₘₐₓ and yₘₐₓ, which are the maximum values of x and y that satisfy Formula (1), are obtained, and each of the values of x and y is adjusted so as to fall within the range of −8% from the minimum value to +8% from the maximum value. Also, it is considered that, in cases where a small quantity of a dopant is contained, the composition in the vicinity of the MPB composition of the ferroelectric oxide extends over the range of approximately +8% with respect to the composition having been obtained for the matrix oxide. However, the lower limit of the minimum value is 0, and the upper limit of the maximum value is 1. Further, in cases where A and B represent the same kind of element, the value of x is not taken into consideration. Furthermore, in cases where C and D represent the same kind of element, the value of y is not taken into consideration.

In accordance with the present invention, the material design is made in the manner described above, and the crystal structure of the ferroelectric oxide is not limited particularly. Examples of the ferroelectric oxides in accordance with the present invention include the perovskite type oxide and an ilmenite type oxide.

Also, the phase structure of the ferroelectric oxide in accordance with the present invention is not limited particularly. Therefore, the ferroelectric oxide in accordance with the present invention may have a two-phase mixed crystal structure, in which the two constituents represented by ACO₃ and BDO₃ coexist. Alternatively, the ferroelectric oxide in accordance with the present invention may have a single-phase structure, in which the two constituents represented by ACO₃ and BDO₃ perfectly form a solid solution.

The composition adjusted in accordance with the present invention embraces the composition, which is adjusted in accordance with the results of calculations having been obtained through direct substitution of numerical values, and the composition, which is adjusted by use of a calibration curve having been obtained from a plurality of pieces of data. Specifically, for example, the process for producing a ferroelectric oxide in accordance with the present invention may be modified such that either one of the A site and the B site in General Formula (a) contains a plurality of kinds of metal elements,

values of the difference E(X)−E(Y) are plotted with respect to the composition of the A site or the B site containing the plurality of kinds of the metal elements, which difference E(X)−E(Y) is the difference between the energy E(X) of the ferroelectric oxide that is represented by General Formula (a), the ferroelectric oxide having the composition of the A site or the B site containing the plurality of kinds of the metal elements, at the time of the crystal structure X, and the energy E(Y) of the ferroelectric oxide that is represented by General Formula (a), the ferroelectric oxide having the composition of the A site or the B site containing the plurality of kinds of the metal elements, at the time of the crystal structure Y,

a calibration curve, which represents the relationship between the composition of the A site or the B site containing the plurality of kinds of the metal elements and the difference E(X)−E(Y), is formed, and

the composition of the A site or the B site containing the plurality of kinds of the metal elements is adjusted by use of the calibration curve such that Formula (1) is satisfied.

As in the cases of the energy, each of the volume V of the fundamental lattice and the spontaneous polarization density vector P in Formula (1) may be of the value utilizing a calibration curve, which has been obtained from a plurality of pieces of data. Alternatively, each of the volume V of the fundamental lattice and the spontaneous polarization density vector P in Formula (1) may be of the calculated value closest to the composition satisfying Formula (1).

The present invention further provides a ferroelectric composition, containing the ferroelectric oxide in accordance with the present invention.

The present invention still further provides a piezoelectric body, containing the ferroelectric oxide in accordance with the present invention. The piezoelectric body in accordance with the present invention may take on the form of a piezoelectric film.

The present invention also provides a piezoelectric device, comprising:
i) the piezoelectric body in accordance with the present invention, and
ii) electrodes for applying an electric field across the piezoelectric body.

The present invention provides the novel material design idea for the ferroelectric oxide which has good piezoelectric performance (good ferroelectric performance). In accordance with the present invention, the composition of the ferroelectric oxide which has good piezoelectric performance (good ferroelectric performance) is capable of being designed easily.

Particularly, the present invention provides the material design idea which is appropriate for the system of the electric field-induced phase transition having been proposed by the inventors in International Patent Publication No. WO2007/034903. In accordance with the present invention, it is possible to provide the ferroelectric oxide having a domain structure, wherein the phase transition is apt to occur, and wherein a large strain displacement quantity is obtained at a comparatively low electric field.

Also, with the ferroelectric oxide in accordance with the present invention, which satisfies Formula (2) or Formula (3) shown above, the difference between the spontaneous polarization density at the stage before the phase transition occurs and the spontaneous polarization density at the stage after the phase transition has occurred is large, and therefore an enhanced strain displacement quantity is obtained.

By the utilization of the ferroelectric oxide in accordance with the present invention, which has been designed in accordance with the material design idea described above, it is possible to provide the piezoelectric device having good piezoelectric performance.

The present invention will hereinbelow be described in further detail with reference to the accompanying drawings.

### BRIEF DESCRIPTION OF THE DRAWINGS

FIG. 1A is an explanatory view showing a piezoelectric gain occurring by ordinary polarization rotation due to phase transition from a rhombohedral system to a tetragonal system,

FIG. 1B is an explanatory view showing how a spontaneous polarization axis rotates at the time at which the phase transition due to an electric field occurs in the system illustrated in FIG. 1A,

FIGS. 2A and 2B are explanatory views, similar to FIGS. 1A and 1B, respectively, showing the cases wherein polarization rotation due to phase transition with an electric field is accompanied by an increase of an absolute value of a spontaneous polarization density,

FIG. 3 is a graph showing a relationship between a tetragonal system extension degree (c/a) and a spontaneous polarization density of each of PZT and Bi type ferroelectric oxides,

FIG. 4 is an explanatory graph showing piezoelectric characteristics of a piezoelectric body containing only a ferroelectric phase, which has characteristics such that, with electric field application, the ferroelectric phase undergoes phase transition to a different ferroelectric phase varying in crystal system,

FIG. 5 is a sectional view showing a major part of an ink jet type recording head (acting as a liquid discharge apparatus), which is provided with an embodiment of the piezoelectric device in accordance with the present invention,

FIG. 6 is a graph showing a calibration curve, in which a value of E(T)−E(R) is plotted with respect to a composition ratio of B site elements in Example 1,

FIG. 7 is a graph showing a calibration curve, in which a value of E(R)−E(T) is plotted with respect to a composition ratio of B site elements in Example 2, and

FIG. 8 is a phase chart of PZT.

### DETAILED DESCRIPTION OF THE INVENTION

### Ferroelectric Oxide

As the process for producing a ferroelectric oxide in accordance with the present invention, the present invention provides the process for producing the ferroelectric oxide having the composition that is represented by General Formula (a) shown below, wherein the composition of the ferroelectric oxide is adjusted such that the most stable crystal structure X of the ferroelectric oxide that is represented by ACO₃ and the most stable crystal structure Y of the ferroelectric oxide that is represented by BDO₃ have different symmetry characteristics and different directions of polarization, and such that Formula (1) shown below is satisfied, and wherein the ferroelectric oxide having the thus adjusted composition is produced. The process for producing a ferroelectric oxide in accordance with the present invention should preferably be modified such that the composition is adjusted such that Formula (2) or Formula (3) shown below is satisfied. Also, in cases where the crystal structure X or the crystal structure Y is of the tetragonal system, the process for producing a ferroelectric oxide in accordance with the present invention should preferably be modified such that the composition is adjusted such that Formula (4) shown below is satisfied.

The ferroelectric oxide in accordance with the present invention has the composition that is represented by General Formula (a) shown below (with the proviso that Pb(Zr,Ti)O₃ is excluded), wherein the ferroelectric oxide has the composition such that the most stable crystal structure X of the ferroelectric oxide that is represented by ACO₃ and the most stable crystal structure Y of the ferroelectric oxide that is represented by BDO₃ have different symmetry characteristics and different directions of polarization, and such that Formula (1) shown below is satisfied. The ferroelectric oxide in accordance with the present invention should preferably be modified such that the ferroelectric oxide has the composition such that Formula (2) or Formula (3) shown below is satisfied. Also, in cases where the crystal structure X or the crystal structure Y is of the tetragonal system, the ferroelectric oxide in accordance with the present invention should preferably be modified such that the ferroelectric oxide has the composition such that Formula (4) shown below is satisfied.

(Aₓ,B₁₋ₓ)(C_{y},D_{1-y})O₃ (a)

In General Formula (a), x represents a number satisfying the condition of 0≦x≦1,

y represents a number satisfying the condition of 0≦y≦1,

each of A and B represents the A site element,

each of C and D represents the B site element,

O represents an oxygen atom,

each of A, B, C and D represents at least one kind of a metal element,

A and B may be of different compositions or may be of a common composition, with the proviso that, in cases where A and B are of the common composition, C and D are of different compositions, and

C and D may be of different compositions or may be of a common composition, with the proviso that, in cases where C and D are of the common composition, A and B are of different compositions.

|E(X)−E(Y)|≦E·PV (1)

In Formula (1), E(X) represents the energy of the ferroelectric oxide that is represented by General Formula (a) shown above at the time of the crystal structure X,

E(Y) represents the energy of the ferroelectric oxide that is represented by General Formula (a) shown above at the time of the crystal structure Y,

P represents the spontaneous polarization density vector at a stage before an electric field is applied,

E represents the actuating electric field vector,

V represents the volume of the fundamental lattice, and

E·P represents the inner product of E and P.

|Px/Py|>1.1 (2)

|Py/Px|>1.1 (3)

In Formula (2) and Formula (3), Px represents the spontaneous polarization density of the ferroelectric oxide that is represented by General Formula (a) at the time of the crystal structure X, and

Py represents the spontaneous polarization density of the ferroelectric oxide that is represented by General Formula (a) at the time of the crystal structure Y.

c/a≧1.008 (4)

In Formula (4), c represents the c-axis length in the crystal structure X or the crystal structure Y which is of the tetragonal system, and

a represents the a-axis length in the crystal structure X or the crystal structure Y which is of the tetragonal system.

As described above under “Description of the Related Art,” in the cases of PZT having the composition in the vicinity of the MPB, the crystal structure is changed by phase transition due to electric field application. As a result, the polarization axis rotates, and high piezoelectric performance is obtained. Also, as reported by the inventors in International Patent Publication No. WO2007/034903, the inventors have proposed a piezoelectric device, comprising: a piezoelectric body containing a first ferroelectric phase, which has crystal orientational characteristics, and which has characteristics such that, with electric field application, at least a part of the first ferroelectric phase undergoes phase transition to a second ferroelectric phase of a crystal system different from the crystal system of the first ferroelectric phase. With the proposed piezoelectric device, a large quantity of the strain displacement is obtained by the displacement due to the rotation of the polarization axis accompanying the phase transition and by the piezoelectric effect accompanying the change of the absolute polarization intensity value of the ferroelectric substance between the stage before the phase transition occurs and the stage after the phase transition has occurred.

Therefore, if the ferroelectric oxide capable of utilizing the phase transition with electric field application, i.e. the ferroelectric oxide having the MPB composition or the composition in the vicinity of the MPB composition, is capable of being adjusted theoretically, it will be possible to provide a ferroelectric oxide having high piezoelectric performance in each of various material systems.

The inventors have found the method of adjusting the composition of the ferroelectric oxide as described above by calculation. In accordance with the present invention, with respect to the composition of the ferroelectric oxide that is represented by General Formula (a) shown above, the material of the ferroelectric oxide capable of forming the MPB is selected firstly. Thereafter, the MPB composition of the selected ferroelectric oxide or the composition in the vicinity of the MPB composition of the selected ferroelectric oxide is adjusted, and the ferroelectric oxide is produced such that the ferroelectric oxide has the thus adjusted composition.

With the process for producing a ferroelectric oxide in accordance with the present invention, the composition is adjusted theoretically, and the ferroelectric oxide having the adjusted composition is produced. Therefore, as for the production technique after the composition has been adjusted, the production technique is not limited and may be selected from a wide variety of techniques, with which the ferroelectric oxide is capable of being produced through composition control such that the adjusted composition is obtained. In the cases of a bulk body, examples of ordinary production techniques for the ferroelectric oxide, in which the composition control is possible, include an ordinary sintering technique, such as an oxide mixing technique. In the cases of a thick film, examples of ordinary production techniques for the ferroelectric oxide, in which the composition control is possible, include a screen printing technique and a green sheet technique. In the cases of a thin film, examples of ordinary production techniques for the ferroelectric oxide, in which the composition control is possible, include a vapor phase technique, such as a pulsed laser deposition technique (a PLD technique), a sputtering technique, or a metalorganic chemical vapor deposition technique (an MOCVD technique); and a liquid phase technique, such as a sol-gel technique or a metalorganic decomposition technique (an MOD technique). Setting conditions necessary for the composition control vary in accordance with the production technique. Therefore, the production conditions, under which the ferroelectric oxide having the adjusted composition is capable of produced, are set in accordance with the selected production technique. (Reference may be made to Examples, which will be described later.)

The selection of the material is made in the manner described below. Specifically, with respect to the ferroelectric oxide that is represented by General Formula (a) shown above, the crystal structure X of the ferroelectric oxide that is represented by ACO₃, which crystal structure is the most stable in terms of energy, and the crystal structure Y of the ferroelectric oxide that is represented by BDO₃, which crystal structure is the most stable in terms of energy, are obtained by calculations. Also, ACO₃ and BDO₃ are adjusted such that the most stable crystal structure X and the most stable crystal structure Y having been obtained by calculations have different symmetry characteristics and different directions of polarization. At the time of the adjustment of the most stable crystal structure X and the most stable crystal structure Y, in cases where ACO₃ and BDO₃ are the oxides having ferromagnetism or antiferromagnetism, the most stable crystal structures are obtained with the type of the ferromagnetism or the antiferromagnetism being taken into consideration. (Reference may be made to Example 2, which will be described later.)

After ACO₃ and BDO₃ having the different most stable crystal structures have been adjusted, with respect to the ferroelectric oxide that is represented by General Formula (a), which ferroelectric oxide is the composite oxide (the solid solution) of ACO₃ and BDO₃, the composition in the vicinity of the MPB composition is adjusted. The MPB composition is the composition at the phase boundary between different crystal structures. Therefore, the ferroelectric oxide having the MPB composition is apt to undergo the phase transition due to a slight change of environment, such as the electric field application. Specifically, in the cases of the MPB composition, the energy E(X) and the energy E(Y) of the crystal structures at the stage before the phase transition occurs and after the phase transition has occurred are approximately identical with each other.

Therefore, the ferroelectric oxide that is represented by General Formula (a) is capable of being set at the MPB composition or the composition in the vicinity of the MPB composition with the processing, wherein the energy E(X) and the energy E(Y) of the ferroelectric oxide that is represented by General Formula (a) at the time of the respective crystal structures are calculated, and wherein the absolute value |E(X)−E(Y)| of the difference between the energy E(X) and the energy E(Y) is set to be closer to 0. In cases where the absolute value |E(X)−E(Y)| falls within the range satisfying Formula (1) shown above, the MPB composition or the composition in the vicinity of the MPB composition is obtained, and the ferroelectric oxide capable of utilizing the phase transition with the electric field application is capable of being obtained. The right side of Formula (1) shown above represents a reference value for the occurrence of phase transition with the actuating electric field. In cases where the ordinary actuating electric field for the piezoelectric device is taken into consideration, Formula (1) should preferably be satisfied with the actuating electric field E falling within the range of 10 kv/cm to 500 kv/cm, and should more preferably be satisfied with the actuating electric field E falling within the range in the vicinity of 200 kV/cm.

In the present invention, no limitation is imposed upon the method of calculating the total energy of the crystal. By way of example, it is possible to employ a method, wherein a Kohn-Sham equation is solved by a first-principles calculation utilizing a density functional method. The calculation of the total energy contains the lattice constant with respect to an assumed crystal structure and an optimization step for atomic coordinates. As the volume of a crystal unit cell to be used in such cases, besides the calculated value, an experimental value may be utilized. Examples of the methods of calculating the total energy of the crystal include a method of molecular orbitals, a molecular dynamics method, and a Monte Carlo method.

In cases where the density functional method is utilized, various approximation methods, such as local density approximation (LDA) and pseudopotential approximation, may be used. Also, in the calculation of the total energy of the composite oxide (the solid solution), there may be utilized a method of approximation of the elemental composition using a super cell in lieu of the crystal unit cell, and a method of approximation of the solid solution forming characteristics, such as a virtual crystal approximation (VCA) method or a KKR method.

The adjustment technique will hereinbelow be described in more detail by taking the cases (A(C,D)O₃), wherein the A site element is represented by A, and wherein the B site element is varied, as an example.

Firstly, a valence number of ion of the A site element is taken into consideration, and the B site element is selected such that the total of the valence number of ion of the A site element and the B site element is equal to six valences. For example, in cases where the A site element exhibits three valences, an element exhibiting three valences may be selected as the B site element (a 33 system). Also, in cases where the A site element exhibits two valences, an element exhibiting four valences may be selected as the B site element (a 24 system). An element Z considered as being the B site element is selected, and the total energy of the oxide represented by AZO₃ is calculated. Further, the most stable crystal structure of AZO₃ is adjusted. In cases where the first-principles calculation is employed as the calculation method, with respect to AZO₃, several crystal symmetry characteristics are assumed, and the total energy is calculated. The thus obtained total energy values are compared with one another, and the crystal structure of the lowest energy is taken as the most stable crystal structure of AZO₃.

The calculation described above is made with respect to a plurality of kinds of the elements Z, and the most stable crystal structures of the various kinds of the oxides represented by AZO₃ are obtained. Also, the two kinds of the oxides represented by AZO₃ (ACO₃ and ADO₃), whose most stable crystal structures have different symmetry characteristics and different directions of polarization, are adjusted.

After ACO₃ and ADO₃ have been adjusted, with respect to the ferroelectric oxide that is represented by A(C,D)O₃, calculations are made to obtain the total energy E(X) at the time of the most stable crystal structure X of ACO₃ and the total energy E(Y) at the time of the most stable crystal structure Y of ADO₃. Also, the composition of A(C,D)O₃ is adjusted such that Formula (1) shown above is satisfied.

As described above, in the calculation of the total energy of the composite oxide (the solid solution) by the first-principles calculation utilizing the density functional method, the method of approximation of the elemental composition using the super cell in lieu of the crystal unit cell is utilized. In such cases, limitation is imposed upon the calculable composition ratio of BiCO₃ and BiDO₃. In such cases, the composition adjustment embraces both the composition, which is obtained from the results of the calculation having been obtained by direct substitution of numerical values, and the composition, which is adjusted by use of the calibration curve having been obtained from a plurality of calculation results. For example, the values of E(X)−E(Y) having been obtained by calculations may be plotted with respect to the C and D composition in A (C,D)O₃, and the calibration curve representing the relationship between the composition and E(X)−E(Y) may be formed. Also, the composition satisfying Formula (1) shown above may be adjusted by use of the calibration curve. (Reference may be made to FIG. 6 for Example 1, which will be described later.) Alternatively, the composition satisfying Formula (1) shown above may be adjusted by the utilization of virtual atoms determined by the composition ratio of C and D by the approximation, such as the VCA method.

The ferroelectric oxide having the composition having been obtained in the manner described above has the MPB composition or the composition in the vicinity of the MPB composition. Therefore, the ferroelectric oxide has high piezoelectric performance (a high piezoelectric gain) by virtue of the rotation of the polarization axis accompanying the phase transition due to electric field application.

As the ferroelectric oxide whose MPB composition has heretofore been already known, PZT as described above under “Description of the Related Art” is well known. The MPB composition varies in accordance with the atom species, which form the composition, and the combination of the atom species and is of the values inherent to the material. Therefore, it is not always possible for an MPB composition to be derived from the values of the known MPB composition or from the values in the vicinity of the known MPB composition. Accordingly, though the searching of MPB compositions has heretofore been conducted, the ferroelectric oxide whose MPB composition has been found out is limited to the oxide capable of being confirmed by ordinary experiments. The present invention makes it possible to find out a novel ferroelectric oxide, which has the MPB composition and which has not yet been known in the past, by calculation and to produce the novel ferroelectric oxide by controlling the production conditions such that the composition having been found out is obtained. General Formula (a) shown above includes PZT having the MPB composition, which has already been known. However, the ferroelectric oxides represented by General Formula (a) shown above, which are other than PZT, are the novel ferroelectric oxides, which have the MPB compositions and which have not yet been found out in the past. Also, it has not heretofore been known that PZT having the MPB composition would satisfy Formula (1) shown above and that Formula (1) would be capable of being utilized positively for the searching of the MPB composition.

As described above under “SUMMARY OF THE INVENTION,” in accordance with the present invention, the material design is made in the manner described above, and the phase structure of the ferroelectric oxide in accordance with the present invention is not limited particularly. Therefore, the ferroelectric oxide in accordance with the present invention may have the two-phase mixed crystal structure, in which the two constituents represented by ACO₃ and BDO₃ coexist. Alternatively, the ferroelectric oxide in accordance with the present invention may have the single-phase structure, in which the two constituents represented by ACO₃ and BDO₃ perfectly form the solid solution. As another alternative, the ferroelectric oxide in accordance with the present invention may have one of other structures.

Also, in accordance with the present invention, by the selection of an element, which is other than Pb, as the A site element, it is possible to adjust the composition of the non-lead type ferroelectric oxide having high piezoelectric performance.

It has heretofore been reported that, in the cases of the Pb type (lead type) ferroelectric oxide, there is a correlation between the piezoelectric performance and the difference |M_{A}−M_{B}|, which is the difference between the mean atomic weight M_{A} of the A site element and the mean atomic weight M_{B} of the B site element. It has also been reported that, in cases where the difference |M_{A}−M_{B}| takes a large value, an electro-mechanical coupling factor k becomes large, and the piezoelectric performance is enhanced. (Reference may be made to “High-efficiency Piezoelectric Single Crystals”, Toshiba Review, Vol. 59, No. 10, pp. 39-42, 2004.) The inventors have found that there is the aforesaid correlation in the cases of the non-lead type ferroelectric oxide.

Therefore, it is considered that, in cases where the A site element and the B site element are selected at the time of the aforesaid composition adjustment such that the difference |M_{A}−M_{B}| takes a large value, it is possible to obtain the piezoelectric performance enhanced even further. For example, an element, which is other than Pb and which has the mass M_{A} as large as possible, may be selected as the A site element, and an element, which has the mass M_{B} as small as possible, may be selected as the B site element. In cases where a judgment is made from the value of the difference |M_{A}−M_{B}| with respect to the lead type ferroelectric oxide described in the aforesaid literature, the difference |M_{A}−M_{B}| should preferably take a value of at least 110.

As an element having a large mass among the elements which are other than Pb and which are capable of constituting the A site element, Bi (209.0) may be mentioned (where the value within the parenthesis represents the atomic weight). Therefore, in accordance with the present invention, the composition of the ferroelectric oxide should preferably be adjusted such that the A site element contains Bi.

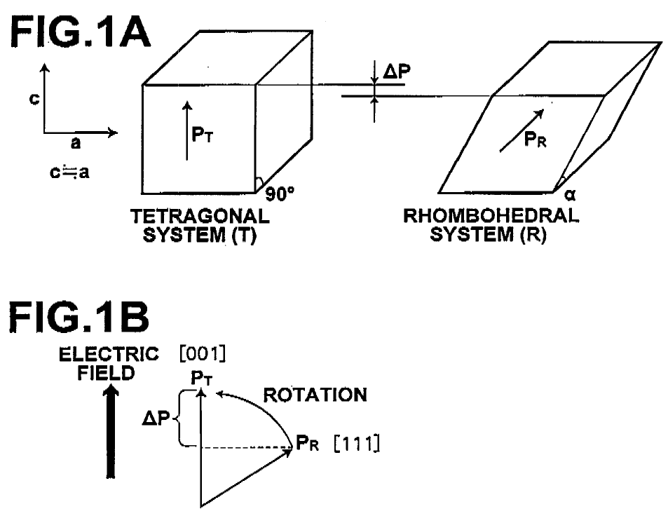

Also, as described above, the ferroelectric oxide in accordance with the present invention has the high piezoelectric performance (the large piezoelectric gain, the large polarization response effect) by virtue of the rotation of the polarization axis (hereinbelow referred to as the polarization rotation) accompanying the phase transition due to the electric field application. FIG. 1A is an explanatory view showing a piezoelectric gain occurring by ordinary polarization rotation. FIG. 1A shows each of the crystal structures and the spontaneous polarization axis of each crystal structure by taking the cases, wherein the polarization rotation due to the phase transition from the rhombohedral system to the tetragonal system is utilized, as an example. Also, FIG. 1B is an explanatory view showing how a spontaneous polarization axis rotates at the time at which the phase transition due to an electric field occurs in the system illustrated in FIG. 1A. As illustrated in FIGS. 1A and 1B, in this system, the spontaneous polarization axis of the rhombohedral system in the [111] direction rotates to the [001] direction due to the phase transition to the tetragonal system, and the spontaneous polarization component in the direction of the electric field application extends by ΔP. The piezoelectric gain is approximately proportional to ΔP. Therefore, as the value of ΔP becomes large, a large piezoelectric gain is obtained.

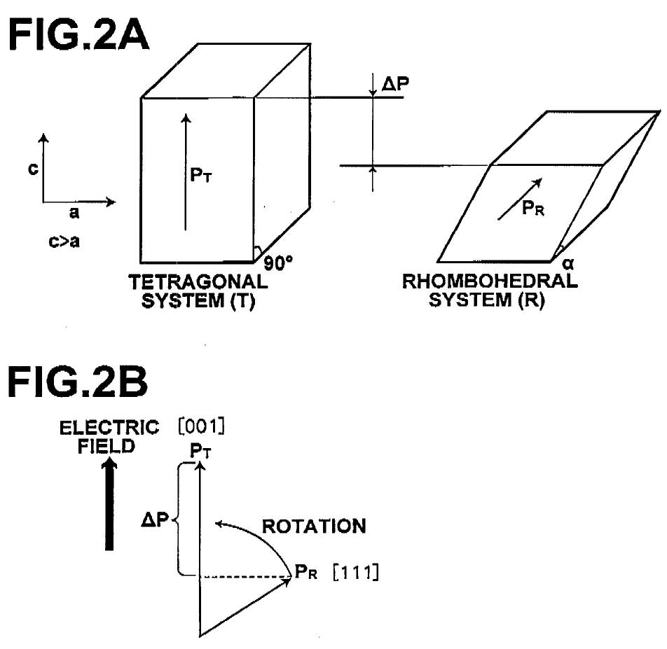

The inventors have paid attention to the characteristics such that, as the difference between the absolute value of the magnitude of the spontaneous polarization density at the stage before the phase transition occurs and the absolute value of the magnitude of the spontaneous polarization density at the stage after the phase transition has occurred becomes large, the value of ΔP, which occurs between the stage before the polarization rotation occurs and the stage after the polarization rotation has occurred, becomes large. The inventors have thus found that it is possible to design the ferroelectric oxide, which has the piezoelectric gain (the polarization response effect) enhanced even further, in cases where, in the composition adjustment made by the aforesaid calculation, calculations are made to obtain the intensity of the spontaneous polarization at the stage before the phase transition occurs and the intensity of the spontaneous polarization at the stage after the phase transition has occurred, and an adjustment is made to set a large ratio between the spontaneous polarization density at the stage before the electric field application is performed (i.e., at the stage before the phase transition occurs) and the spontaneous polarization density at the stage after the phase transition has occurred. FIGS. 2A and 2B are explanatory views, similar to FIGS. 1A and 1B, respectively, showing a piezoelectric gain obtained by polarization rotation in cases where the difference between the absolute value of the magnitude of the spontaneous polarization density at the stage before the phase transition occurs and the absolute value of the magnitude of the spontaneous polarization density at the stage after the phase transition has occurred is large.

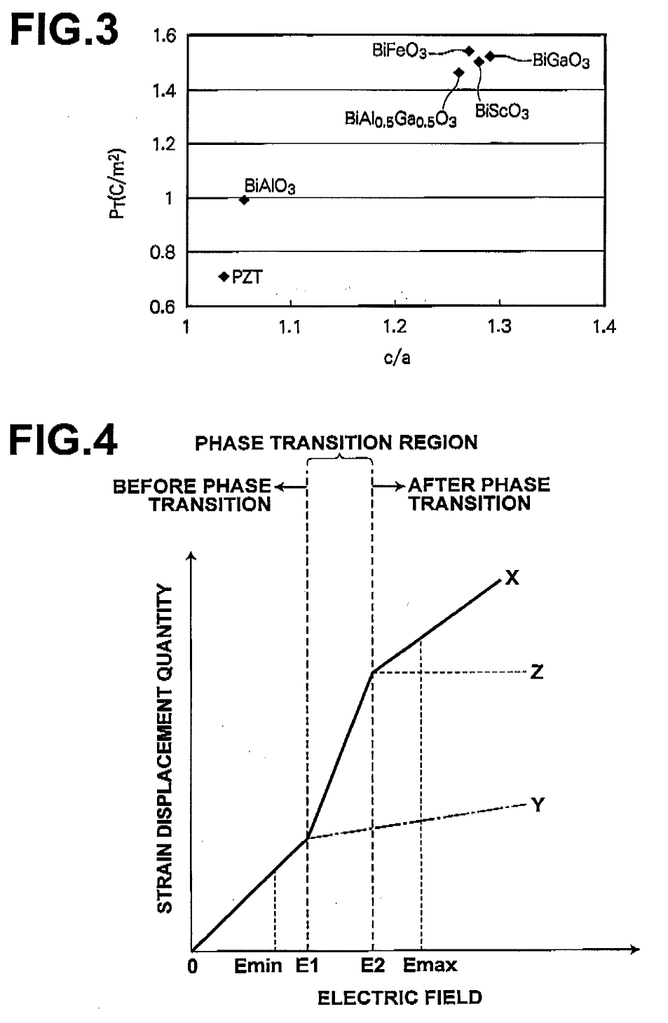

In the system illustrated in FIGS. 2A and 2B, the length of the c-axis of the tetragonal system, which is the crystal system obtained at the stage after the phase transition has occurred, is longer than the length of the a-axis of the tetragonal system (i.e., c/a>0). The entire system thus extends markedly in the c-axis direction due to the phase transition. Therefore, the quantity of the displacement in the c-axis direction is large, and the piezoelectric characteristics are high. Also, since the value of c/a is large, the atomic displacement is large in the c-axis direction, and the absolute value of the spontaneous polarization density is large. FIG. 3 is a graph showing a relationship between a tetragonal system extension degree (c/a) and a spontaneous polarization density of each of PZT and Bi type ferroelectric oxides. FIG. 3 illustrates that, as the c/a value becomes large, the spontaneous polarization density is high. Therefore, with the system illustrated in FIGS. 2A and 2B, besides the piezoelectric gain due to the polarization rotation effect of the change of the direction of the spontaneous polarization axis, the large piezoelectric gain is obtained by the effect of markedly extending the entire system in the c-axis direction. Also, since a large change of the absolute value of the polarization intensity is obtained between the stage before the phase transition occurs and the stage after the phase transition has occurred, a large piezoelectric e coefficient is obtained, and the piezoelectric device having a high sensitivity is obtained.

Currently, piezoelectric devices are required to have the characteristics such that a piezoelectric constant d₃₃ is equal to at least 200 pm/V. In cases where the crystal system obtained at the stage after the phase transition has occurred is the crystal structure X, the spontaneous polarization density Px and the spontaneous polarization density Py should preferably satisfy Formula (2) shown below. Also, in cases where the crystal system obtained at the stage after the phase transition has occurred is the crystal structure Y, the spontaneous polarization density Px and the spontaneous polarization density Py should preferably satisfy Formula (3) shown below. In such cases, by the piezoelectric effect with the polarization rotation, the piezoelectric constant d₃₃ of at least 200 pm/V is obtained.

|Px/Py|>1.1 (2)

|Py/Px|>1.1 (3)

Also, in cases where the crystal system obtained at the stage after the phase transition has occurred is the tetragonal system, and Formula (4) shown below is satisfied, the piezoelectric constant d₃₃ of at least 200 pm/V is obtained. Specifically, in order for the piezoelectric constant d₃₃ of 200 pm/V to be obtained by the utilization of the electric field-induced phase transition from the rhombohedral system to the tetragonal system by the application of electric field of 200 kV/cm, if it is considered that the rhombohedral system may be approximately represented by a cubic system, a strain η toward the c-axis direction may be equal to approximately 0.008. More specifically, in cases where it is assumed that little change arises with the lattice constant length in the a-axis direction due to the transition, the condition of c/a≧1.008 may be satisfied.

c/a≧1.008 (4)

In Formula (4), c represents the c-axis length in the crystal structure X or the crystal structure Y which is of the tetragonal system, and a represents the a-axis length in the crystal structure X or the crystal structure Y which is of the tetragonal system.

The value of ΔP is the difference of the spontaneous polarization density in the direction of the electric field application. Therefore, with respect to the system illustrated in FIGS. 2A and 2B, in cases where Formula (2) or Formula (3) shown above is satisfied, by the electric field-induced phase transition accompanied by the polarization rotation, both the effect of the rotation and the effect of the magnitude of the absolute value of the spontaneous polarization density described above are obtained.

The calculation of each of the spontaneous polarization density Px and the spontaneous polarization density Py may be made with, for example, the first-principles calculation by use of the lattice constant and the atomic coordinates, which have been optimized in the total energy calculation described above, and by the utilization of a Berry phase method with respect to the intensity of the polarization.

With respect to the ferroelectric oxide satisfying Formula (2) or Formula (3), nothing has heretofore been reported. As for PZT, which has been known as having a high piezoelectric effect due to the phase transition with the MPB composition, a value of approximately 1 is taken, and the change of the absolute value is small. (Reference may be made to Table 3 shown later.) In accordance with the present invention, by the calculation described above, it is possible to adjust the composition of the ferroelectric oxide such that the polarization rotation due to the phase transition is capable of being utilized, and such that the difference between the absolute value of the spontaneous polarization density at the stage before the phase transition occurs and the absolute value of the spontaneous polarization density at the stage after the phase transition has occurred is large.

Also, with the system of the electric field-induced phase transition proposed in International Patent Publication No. WO2007/034903, the characteristics are obtained such that, with electric field application, at least a part of the first ferroelectric phase undergoes phase transition to the second ferroelectric phase of a crystal system different from the crystal system of the first ferroelectric phase. Therefore, with the proposed system, a piezoelectric gain enhanced even further is obtained. The system of the electric field-induced phase transition proposed by the inventors in International Patent Publication No. WO2007/034903 will be described hereinbelow.

FIG. 4 is an explanatory graph showing a relationship between an electric field and a strain displacement quantity with respect to each of a piezoelectric body (indicated by a straight line X) containing only a ferroelectric phase, which has characteristics such that, with electric field application, the ferroelectric phase undergoes phase transition to a different ferroelectric phase varying in crystal system, a conventional piezoelectric body (indicated by a straight line Y) in which the polarization rotation due to the phase transition is not utilized, and a piezoelectric body (indicated by a straight line Z), which is a ferroelectric substance at the stage before the phase transition occurs, and which is converted into a paraelectric substance after the phase transition has occurred. As an aid in facilitating the comparison, as for the range of the electric field of 0 to E1, the piezoelectric characteristics of the straight lines X, Y, and Z are matched with one another. Also, as for the range of the electric field of E1 to E2, the piezoelectric characteristics of the straight lines X and Z are matched with each other.

In FIG. 4, the electric field E1 represents the minimum electric field at which the phase transition of the ferroelectric phase begins. Also, the electric field E2 represents the electric field at which the phase transition of the ferroelectric phase finishes approximately perfectly. Ordinarily, the relationship between E1 and E2 may be such that E1<E2. However, the relationship between E1 and E2 may often be such that E1=E2. The term “electric field E2 at which phase transition of a ferroelectric phase finishes approximately perfectly” as used herein means the electric field such that further phase transition does not occur with the further application of a higher electric field. It may often occur that, in cases where an electric field higher than E2 is applied across the piezoelectric body, a part of the ferroelectric phase remains without undergoing the phase transition.

As illustrated in FIG. 4, the piezoelectric body has the piezoelectric characteristics described below. Specifically, as for the range of the electric field E of 0 to E1 (i.e., at the stage before the phase transition occurs), by virtue of the piezoelectric effect of the ferroelectric phase at the stage before the phase transition occurs, the strain displacement quantity increases linearly in accordance with the increase in electric field. Also, as for the range of the electric field E of E1 to E2, the volume change due to the change of the crystal structure accompanying the phase transition occurs, and the strain displacement quantity increases linearly in accordance with the increase in electric field. Further, as for the range of the electric field E of E≧E2 (i.e., at the stage after the phase transition has finished approximately perfectly), by virtue of the piezoelectric effect of the ferroelectric phase at the stage after the phase transition has occurred, the strain displacement quantity increases linearly in accordance with the increase in electric field.

With the piezoelectric body described above, the volume change due to the change of the crystal structure accompanying the phase transition arises (as for the range of the electric field E of E1 to E2). Also, the piezoelectric body contains the ferroelectric substance at both the stage before the phase transition occurs and the stage after the phase transition has occurred. Therefore, the piezoelectric effect of the ferroelectric substance is obtained at both the stage before the phase transition occurs and the stage after the phase transition has occurred. Accordingly, as for all of the range of the electric field E of 0 to E1, the range of the applied electric field E of E1 to E2, and the range of the applied electric field E of E≧E2, a large strain displacement quantity is obtained.

With the conventional piezoelectric devices, ordinarily, the electric field is applied in the direction matched with the spontaneous polarization axis of the ferroelectric substance, and the piezoelectric effect extending in the direction of the spontaneous polarization axis is thereby utilized (FIG. 4, the straight line Y). As indicated by the straight line Y, as for the electric field range of zero to a certain electric field, the strain displacement quantity increases linearly with respect to the increase in electric field. However, as indicated by the straight line Y, as for the electric field range higher than the certain electric field, the increase in strain displacement quantity with respect to the increase in electric field becomes markedly small, and saturation is approximately reached in strain displacement quantity.

Also, in the cases of the system having the piezoelectric characteristics indicated by the straight line Z illustrated in FIG. 4, as for the electric field range before the phase transition occurs, the strain displacement quantity increases linearly with respect to the increase in electric field due to the piezoelectric effect of the ferroelectric phase. The straight line Z also indicates that, as for the electric field range of an electric field E1, at which the phase transition begins, to an electric field E2, at which the phase transition is approximately completed, the strain displacement quantity increases due to the change of the crystal structure accompanying the phase transition. The straight line Z further indicates that, as for the electric field range higher than the electric field E2, at which the phase transition to the paraelectric phase is approximately completed, since the piezoelectric effect of the ferroelectric phase is not obtained any more, the strain displacement quantity does not increase with further application of the electric field.

With the piezoelectric body containing the ferroelectric phase, which has the characteristics such that, with the electric field application, the ferroelectric phase undergoes phase transition to a different ferroelectric phase varying in crystal system, a larger strain displacement quantity than with the conventional piezoelectric body is obtained. The piezoelectric body should preferably be actuated under the conditions such that a minimum electric field Emin and a maximum electric field Emax satisfy Formula (5) shown below, and should more preferably be actuated under the conditions such that the minimum electric field Emin and the maximum electric field Emax satisfy Formula (6) shown below.

Emin<E1<Emax (5)

Emin<E1≦E2<Emax (6)

In the cases of the system of the electric field-induced phase transition described above, the ferroelectric phase which is to undergo the phase transition, should preferably have the crystal orientational characteristics in a direction different from the direction of the spontaneous polarization axis, and should more preferably have the crystal orientational characteristics in the direction approximately identical with the direction of the spontaneous polarization axis of the ferroelectric phase, which is formed after the phase transition has occurred. Ordinarily, the direction of the crystal orientation is the direction of the electric field application.

In cases where the direction of the electric field application is set to be approximately identical with the direction of the spontaneous polarization axis of the ferroelectric phase, which is formed after the phase transition has occurred, by virtue of an engineered domain effect, a larger displacement quantity is obtained than in cases where the direction of the electric field application is matched with the direction of the spontaneous polarization axis of the ferroelectric phase at the stage before the phase transition occurs. The engineered domain effect of single crystals is described in, for example, a literature “Ultrahigh strain and piezoelectric behavior in relaxor based ferroelectric single crystals”, S. E. Park et al., Journal of Applied Physics, Vol. 82, Issue 4, pp. 1804-1811, 1997.

Also, in cases where the direction of the electric field application is set to be approximately identical with the direction of the spontaneous polarization axis of the ferroelectric phase, which is formed after the phase transition has occurred, the phase transition is apt to occur more easily. This will presumably since the state, in which the direction of the spontaneous polarization axis and the direction of the electric field application are matched with each other, is favorable for a high crystallographic stability, and the ferroelectric phase is apt to undergo the phase transition to the crystal system having an enhanced stability. It may often occur that, in cases where an electric field higher than the electric field E2 is applied across the piezoelectric body, a part of the ferroelectric phase remains without undergoing the phase transition. However, since the phase transition proceeds efficiently, the proportion of the part of the ferroelectric phase, which part remains without undergoing the phase transition in cases where an electric field higher than the electric field E2 is applied across the piezoelectric body, is kept small. As a result, a larger strain displacement quantity is obtained reliably than in cases where the direction of the electric field application is matched with the direction of the spontaneous polarization axis of the ferroelectric phase before undergoing the phase transition.

Further, after the phase transition has occurred, the direction of the electric field application approximately coincides with the direction of the spontaneous polarization axis of the ferroelectric phase. Therefore, the piezoelectric effect of the ferroelectric phase, which is formed after the phase transition has occurred, arises efficiently, and a larger strain displacement quantity is obtained reliably.

As described above, in cases where the direction of the electric field application is set to be approximately identical with the direction of the spontaneous polarization axis of the ferroelectric phase, which is formed after the phase transition has occurred, a large strain displacement quantity is obtained at all of the stage before the phase transition occurs, the stage during the phase transition, and the stage after the phase transition has occurred. The effects described above are obtained at least in cases where the direction of the spontaneous polarization axis of the ferroelectric phase at the stage before the phase transition occurs is different from the direction of the electric field application. The effects described above are enhanced even further in cases where the direction of the electric field application is close to the direction of the spontaneous polarization axis of the ferroelectric phase, which is formed at the stage after the phase transition has occurred.

In accordance with the present invention, by the selection of the material having the ferroelectric characteristics before and after the phase transition, it is possible to adjust the composition of the ferroelectric oxide, which has the characteristics such that, with the electric field application, the ferroelectric oxide undergoes the phase transition to a different ferroelectric phase varying in crystal system, as described in International Patent Publication No. WO2007/034903.

As described above, the present invention provides the novel material design idea for the ferroelectric oxide which has good piezoelectric performance (good ferroelectric performance). In accordance with the present invention, the composition of the ferroelectric oxide which has good piezoelectric performance (good ferroelectric performance) is capable of being designed easily.

Particularly, the present invention provides the material design idea which is appropriate for the system of the electric field-induced phase transition having been proposed by the inventors in International Patent Publication No. WO2007/034903. In accordance with the present invention, it is possible to provide the ferroelectric oxide having a domain structure, wherein the phase transition is apt to occur, and wherein a large strain displacement quantity is obtained at a comparatively low electric field.

Also, with the ferroelectric oxide in accordance with the present invention, which satisfies Formula (2) or Formula (3) shown above, the difference between the spontaneous polarization density at the stage before the phase transition occurs and the spontaneous polarization density at the stage after the phase transition has occurred is large, and therefore an enhanced strain displacement quantity is obtained.

### [Ferroelectric Composition]

The ferroelectric composition in accordance with the present invention is characterized by containing the ferroelectric oxide in accordance with the present invention, which has been designed by the aforesaid material design in accordance with the present invention.

The ferroelectric composition in accordance with the present invention may also contain an arbitrary constituent other than the ferroelectric oxide in accordance with the present invention, such as a ferroelectric oxide other than the ferroelectric oxide in accordance with the present invention, an additive element, or a sintering auxiliary.

### [Piezoelectric Device (Ferroelectric Device) and Ink Jet Type Recording Head]

The piezoelectric device (the ferroelectric device) in accordance with the present invention comprises: (i) the piezoelectric body containing the ferroelectric oxide in accordance with the present invention having been designed by the material design in accordance with the present invention, and (ii) the electrodes for applying an electric field across the piezoelectric body.

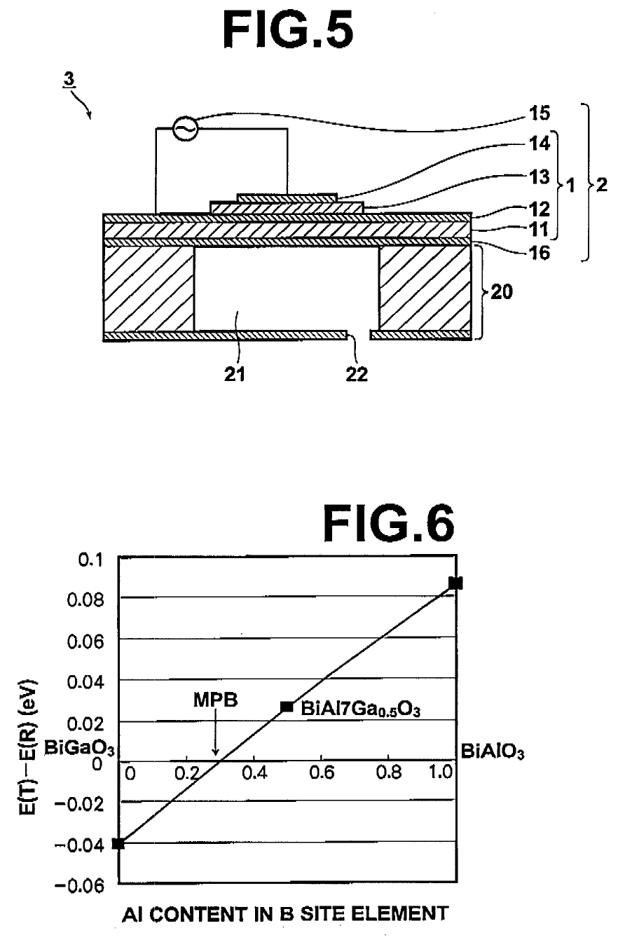

The piezoelectric device in accordance with the present invention, which utilizes the ferroelectric oxide in accordance with the present invention, has the high piezoelectric performance. An embodiment of the piezoelectric device in accordance with the present invention, and an ink jet type recording head (acting as a liquid discharge apparatus), which is provided with the piezoelectric device, will be described hereinbelow with reference to FIG. 5.

FIG. 5 is a sectional view showing a major part of an ink jet type recording head (acting as a liquid discharge apparatus), which is provided with an embodiment of the piezoelectric device in accordance with the present invention, the sectional view being taken in the thickness direction of the piezoelectric device. In FIG. 5, for clearness, reduced scales of constituent elements of the ink jet type recording head are varied from actual reduced scales.

With reference to FIG. 5, a piezoelectric device 1 comprises a substrate 11. The piezoelectric device 1 also comprises a bottom electrode 12, a piezoelectric body 13, and a top electrode 14, which are overlaid in this order on a surface of the substrate 11. The piezoelectric body 13 is a polycrystal constituted of the ferroelectric oxide in accordance with the present invention having been designed by the material design in accordance with the present invention. (The polycrystal may contain inevitable impurities.)

No limitation is imposed upon a material of the substrate 11. Examples of the materials of the substrate 11 include silicon, glass, stainless steel (SUS), yttrium stabilized zirconia (YSZ), alumina, sapphire, and silicon carbide. The substrate 11 may also be constituted of a laminate substrate, such as an SOI substrate, which contains an SiO₂ film and an Si active layer laminated in this order on a silicon substrate.

No limitation is imposed upon a principal constituent of the bottom electrode 12. Examples of the principal constituents of the bottom electrode 12 include metals, such as Au, Pt, and Ir; metal oxides, such as IrO₂, RuO₂, LaNiO₃, and SrRuO₃; and combinations of the above-enumerated metals and/or the above-enumerated metal oxides. Also, no limitation is imposed upon a principal constituent of the top electrode 14. Examples of the principal constituents of the top electrode 14 include the materials exemplified above for the bottom electrode 12; electrode materials ordinarily utilized in semiconductor processes, such as Al, Ta, Cr, and Cu; and combinations of the materials exemplified above for the bottom electrode 12 and/or the above-enumerated electrode materials. No limitation is imposed upon the thickness of each of the bottom electrode 12 and the top electrode 14. However, the thickness of each of the bottom electrode 12 and the top electrode 14 should preferably fall within the range of 50 nm to 500 nm.

A piezoelectric actuator 2 is provided with the piezoelectric device 1. The piezoelectric actuator 2 is also provided with a vibrating plate 16, which is secured to a rear surface of the substrate 11 of the piezoelectric device 1 and is capable of being vibrated by expansion and contraction of the piezoelectric body 13. The piezoelectric actuator 2 is further provided with control means 15, such as an actuation circuit for actuating the piezoelectric device 1.

An ink jet type recording head (acting as a liquid discharge apparatus) 3 approximately has a constitution, in which an ink nozzle (acting as a liquid storing and discharging member) 20 is secured to a rear surface of the piezoelectric actuator 2. The ink nozzle 20 comprises an ink chamber (acting as a liquid storing chamber) 21, in which ink is to be stored. The ink nozzle 20 also comprises an ink discharge opening (acting as a liquid discharge opening) 22, through which the ink is to be discharged from the ink chamber 21 to the exterior of the ink chamber 21.

The ink jet type recording head 3 is constituted such that the piezoelectric device 1 is expanded or contracted through alteration of the electric field applied across the piezoelectric device 1, and such that the discharge of the ink from the ink chamber 21 and the quantity of the ink discharged from the ink chamber 21 are thereby controlled.

In lieu of the vibrating plate 16 and the ink nozzle 20 being secured as the independent members to the substrate 11, a part of the substrate 11 may be processed to form the vibrating plate 16 and the ink nozzle 20. For example, in cases where the substrate 11 is constituted of the laminate substrate, such as the SOI substrate, etching processing may be performed on the substrate 11 from the rear surface side of the substrate 11 in order to form the ink chamber 21, and the vibrating plate 16 and the ink nozzle 20 may be formed with the processing of the substrate 11.

No limitation is imposed upon the form of the piezoelectric body 13. However, in the cases of the piezoelectric devices for use in the ink jet type recording heads, such that images having good image quality may be obtained, it has recently been studied to enhance array density of the piezoelectric devices. Further, such that the array density of the piezoelectric devices may be enhanced, it has recently been studied to reduce the thicknesses of the piezoelectric devices. Therefore, in cases where the reduction of the thickness of the piezoelectric device is taken into consideration, the piezoelectric body 13 should preferably take on the form of a piezoelectric film, and should more preferably take on the form of a thin piezoelectric film having a thickness of at most 20 μm. The ferroelectric oxide in accordance with the present invention, which has the high piezoelectric constant, is efficient for the thin film required to have a high piezoelectric constant.

In this embodiment, the piezoelectric body 13, which contains the ferroelectric oxide in accordance with the present invention, is the ferroelectric oxide having the MPB composition or the composition in the vicinity of the MPB composition, i.e., the ferroelectric oxide capable of utilizing the phase transition with the electric field application. In cases where the piezoelectric device 1 is constituted as the non-lead type piezoelectric device, the piezoelectric body 13 should preferably be constituted of the ferroelectric oxide in accordance with the present invention containing Bi.

Basically, this embodiment of the piezoelectric device 1 should preferably be designed such that the phase transition of the piezoelectric body 13 may be performed only with the alteration of the electric field. Specifically, the selection of the composition of the piezoelectric body 13 and the selection of the kinds of the crystal systems, between which the phase transition is to occur, should preferably be made such that the system has the phase transition temperature at the service ambient temperature. However, when necessary, a temperature adjustment may be performed such that the device temperature coincides with the phase transition temperature. In cases where the piezoelectric device 1 is thus actuated at the phase transition temperature or at the temperature in the vicinity of the phase transition temperature, the phase transition occurs efficiently.

This embodiment of the piezoelectric device 1 comprises the piezoelectric body 13 containing the ferroelectric oxide in accordance with the present invention having been designed by the material design in accordance with the present invention. Therefore, the piezoelectric device 1 exhibits the high piezoelectric performance even at a comparatively low electric field.

### [Design Modification]

In the embodiment described above, by way of example, the ferroelectric device containing the ferroelectric oxide in accordance with the present invention is constituted as the piezoelectric device. However, the ferroelectric oxide in accordance with the present invention is applicable also to a ferroelectric device other than the piezoelectric device. Examples of the ferroelectric devices other than the piezoelectric device include ferroelectric memories.

### EXAMPLES

The present invention will further be illustrated by the following non-limitative examples.

### Example 1

With respect to a ferroelectric oxide in which the A site element was Bi, composition design for the MPB composition or the composition in the vicinity of the MPB composition was made by the first-principles calculation utilizing the density functional method. For the calculation, the density functional method based upon the LDA method, in which the plane wave development was used, was employed. For the optimization of the lattice constant and the atomic coordinates, a projector augmented-wave method (a PAW method) and ultra-soft pseudopotential were used. The cut-off energy of the plane wave development of the electron wave function was 60.0 Ry, and the wave function was calculated at each of k points having been formed automatically with Brillouin zone 6×6×6Monkhorst-Pack grid. The optimization of the lattice constant and the atomic coordinates was performed until an interatomic force became at most 0.1 mRy/Bohr. The energy unit Ry (Rydberg) was the energy unit principally utilized for band calculation and converted as 1 Ry=13.6 eV.

As the B site elements, Al and Ga were selected. There were assumed a ferroelectric rhombohedral system represented by crystal symmetric group symbols of R3m and R3c, a ferroelectric tetragonal system represented by P4mm, a paraelectric rhombohedral system having central symmetry and represented by R 3̅c, and a paraelectric cubic system represented by Fm3m. The spontaneous polarization density was calculated by the utilization of the energy of each of the assumed crystal systems and the Berry phase. Of the crystal symmetric group symbols described above, the cases of R3c and R 3̅c represent the ilmenite type oxide, and the other cases represent the perovskite type oxide. The energy obtained by the calculation is listed in Table 1 shown below. The lattice constant is listed in Table 2 shown below. The spontaneous polarization density is listed in Table 3 shown below. The spontaneous polarization density was calculated with respect to each of the most stable crystal structures, and the ratio of the spontaneous polarization density between the respective crystal structures was calculated. For comparison, the results of the calculation made in the same manner with respect to PZT are also listed in Table 3.

In Table 1, the energy was represented in units of eV. The energy of the crystal structure was represented by the relative value with respect to the energy of the most stable crystal structure, which energy was taken as the reference value. As shown in Table 1, the most stable crystal structure of BiGaO₃ was the tetragonal system (P4mm), and the most stable crystal structure of BiAlO₃ was the rhombohedral system (R3c). Therefore, it was confirmed that BiGaO₃ and BiAlO₃ were capable of being selected as BiZO₃ (BiCO₃ and BiDO₃) having the characteristics such that the most stable crystal structures had different symmetry characteristics and different directions of polarization.

Also, as shown in Table 2, in the cases of the tetragonal system, each of BiGaO₃ and BiAlO₃ had a high lattice constant ratio (c/a value≧1.008). As shown in Table 3, in the cases of the tetragonal system, each of BiGaO₃ and BiAlO₃ had a high spontaneous polarization density and had the P_{T}/P_{R} ratio sufficiently higher than 1.1 (the P_{T}/P_{R} ratio being the ratio of the spontaneous polarization density P_{T} of the tetragonal system to the spontaneous polarization density P_{R} of the rhombohedral system). Further, the spontaneous polarization density P_{T} of BiGaO₃ in the cases of the tetragonal system was the maximum value among the values of the currently known ferroelectric substances. When a comparison was made with the value of PZT, it was confirmed that the spontaneous polarization density P_{T} of BiGaO₃ in the cases of the tetragonal system was markedly high. Furthermore, as for BiAlO₃, the spontaneous polarization density P_{T} was higher than the spontaneous polarization density P_{T} of PZT. Therefore, from Table 3, with respect to the composite oxide of BiGaO₃ and BiAlO₃, it was considered that the value of ΔP occurring between the stage before the occurrence of the electric field-induced phase transition and after the occurrence of the electric field-induced phase transition became large by virtue of the effect of the polarization rotation due to the phase transition and the effect of the large P_{T}/P_{R} ratio of the spontaneous polarization densities.

TABLE 1

| BiGaO₃ (eV) | BiAlO₃ (eV) |
|---|---|
| 0.765 (Fm3m para) | 0.267 (Fm3m) |
| 0.234 (R 3̅c para) | 0.086 (P4mm) |
| 0.185 (R3m) | 0.072 (R 3̅c) |
| 0.041 (R3c) | 0.047 (R3m) |
| 0.000 (P4mm) | 0.000 (R3c) |

TABLE 2

| | | BiGaO₃ | BiAlO₃ |
|---|---|---|---|
| Tetragonal | a-axis (Å) | 3.63 | 3.69 |
| system (P4mm) | c/a | 1.29 | 1.055 |
| Rhombohedral | a-axis (Å) | 3.88 | 3.77 |
| system (R3c) | (aᵣ/\sqrt{2}) | | |
| | α (°) | 59.736 | 59.740 |

TABLE 3

| | BiGaO₃ | BiAlO₃ | PZT |
|---|---|---|---|
| | (C/m²) | (C/m²) | (C/m²) |
| P_{T} (spontaneous | 0.99 | 1.52 | 0.71 |
| polarization density of | (P4mm) | (P4mm) | (I4mm) |
| tetragonal system) | | | |
| P_{R} (spontaneous | 0.88 | 0.83 | 0.67 |
| polarization density of | (R3c) | (R3c) | (R3m) |
| rhombohedral system) | | | |
| P_{T}/P_{R} | 1.13 | 1.83 | 0.94 |
| Stable structure | R3c | P4mm | R3m |

Thereafter, the composition adjustment was made for Bi(Al,Ga)O₃ such that Formula (1) shown above might be satisfied. Firstly, with respect to Bi(Al_{0.5},Ga_{0.5})O₃ in which Al:Ga=50:50, the calculation of the total energy by the first-principles calculation (under the conditions identical as those described above) using the super cell was made. Also, the calculation of the spontaneous polarization density with the Berry phase was made. As for the super cell, the structure, in which the B site atoms Al and Ga were arrayed alternately in the [111] direction, was employed. Therefore, the crystal group of the rhombohedral system had the R3 structure, and the crystal group of the tetragonal system had the 14 mm structure. The tetragonal system of each of BiGaO₃ and BiAlO₃ having the simple perovskite structure had the P4mm structure. For the calculation, the tetragonal system, which was the most stable crystal structure of BiGaO₃, and the rhombohedral system, which was the most stable crystal structure of BiAlO₃, were assumed. The lattice constant obtained by the calculation is listed in Table 4 shown below. The total energy and the spontaneous polarization density are listed in Table 5 shown below. In Table 5, as in Table 1, the energy of the crystal structure was represented by the relative value with respect to the energy of the most stable crystal structure, which energy is taken as the reference value.

As shown in Table 5, as for Bi(Al_{0.5},Ga_{0.5})O₃, the energy difference between the rhombohedral system (R3) and the tetragonal system (I4mm), which were the most stable crystal structures, was equal to 0.026 eV. The energy difference was thus smaller than the energy difference (0.041) between the rhombohedral system (R3c) and the tetragonal system (P4mm) of BiGaO₃ shown in Table 1 and the energy difference (0.086) between the rhombohedral system (R3c) and the tetragonal system (P4mm) of BiAlO₃ shown in Table 1. It was thus indicated that, in cases where BiGaO₃ and BiAlO₃ varying in most stable crystal structure formed the composite oxide (the solid solution) together with each other, the energy difference between the tetragonal system and the rhombohedral system became small, and the phase transition with the electric field application became apt to occur.

Also, as shown in Table 4, as for Bi(Al_{0.5},Ga_{0.5})O₃, the lattice constant ratio in the cases of the tetragonal system was equal to 1.26. Further, as shown in Table 5, as for Bi(Al_{0.5},Ga_{0.5})O₃, the spontaneous polarization density in the cases of the tetragonal system was equal to 1.46 and was thus markedly high, and the P_{T}/P_{R} ratio was equal to approximately 1.66. It was thus confirmed that, in cases where BiGaO₃ and BiAlO₃ formed the composite oxide (the solid solution) together with each other, the large difference between the absolute values of the polarization intensities is retained as in the cases of the simple substances of BiGaO₃ and BiAlO₃. It was also confirmed that, in cases where BiGaO₃ and BiAlO₃ formed the composite oxide (the solid solution) together with each other, by the utilization of the MPB, both the displacement due to the rotation of the polarization axis accompanying the phase transition and the displacement due to the large increase of the absolute value of the polarization intensity were obtained, and the markedly large piezoelectric gain (the markedly large polarization response effect) might be expected.

TABLE 4

| | | Bi(Al_{0.5}Ga_{0.5})O₃ |
|---|---|---|
| Tetragonal | a-axis (Å) | 3.62 |
| system (I4mm) | c/a | 1.26 |
| Rhombohedral | a-axis (Å) | 3.82 |
| system (R3) | (aᵣ/\sqrt{2}) | |
| | α (°) | 59.756 |

TABLE 5

| Crystal structure | Total energy | Spontaneous polarization |
|---|---|---|
| Bi(Al_{0.5}Ga_{0.5})O₃ | (eV) | density P (C/m²) |
| R3m | 0.092 | 1.09 |
| I4mm | 0.026 | 1.46 |
| R3 | 0.000 | 0.88 |

Thereafter, in order for the composition in the vicinity of the MPB composition of Bi(Al,Ga)O₃ to be adjusted, the values of tetragonal system−rhombohedral system energy difference E(T)−E(R) were plotted with respect to the Al and Ga composition, and the calibration curve representing the relationship between the composition and E(T)−E(R) was formed (FIG. 6). The method of least squares was employed for the formation of the calibration curve. With respect to the right side in Formula (1) shown above, the actuating electric field E was set at E=200 kV/cm, and the polarization intensity P was set at P=0.88 C/cm² (the value of the rhombohedral system of Bi(Al_{0.5}, Ga_{0.5})O₃). Also, the calculation was made on the assumption that the system was the rhombohedral system, that the polarization was directed toward the [111] direction, and that the electric field was directed toward the [001] direction. The energy units were converted into eV, and as a result a value of approximately 0.004 eV was obtained. From FIG. 6, it was found that the composition, in which the Al:Ga ratio fell within the range between 28:72 and 34:66, might be the ferroelectric oxide capable of utilizing the structure phase transition induced by the electric field application. In the cases of the Bi type oxide, as for the polarization intensity P, in cases where the crystal structure is identical, the polarization value of the simple substance is applicable to the solid solution.

In the cases of a thin film or in cases where a small quantity of a dopant is introduced, the range of −8% from the minimum value to +8% from the maximum value may be taken into consideration, and it may be regarded that the composition, in which the Al:Ga ratio falls within the range between 20:80 and 42:58, might be the ferroelectric oxide capable of utilizing the structure phase transition induced by the electric field application. Also, since the value of E(T)−E(R) is equal to approximately 0 in cases where the ratio of Al:Ga is in the vicinity of Al:Ga=30:70, it may be considered that Bi(Al_{0.3},Ga_{0.7})O₃ is approximately the substance having the MPB composition ratio.

Thereafter, a (100) SrTiO₃ substrate was prepared. An SrRuO₃ bottom electrode having a film thickness of 0.2 μm was formed on the surface of the substrate by the PLD method under the conditions of the substrate temperature of 650° C. A ferroelectric film having a film thickness of 200 nm was then formed by the PLD method by use of a target having a composition of Bi_{1.1}Al_{0.3}Ga₀O₇O₃ under the conditions of a laser beam intensity of 300 mJ, a laser pulse frequency of 5 Hz, an oxygen partial pressure of 6.7 Pa, a substrate-target spacing distance of 50 mm, a target rotation speed of 9.7 rpm, and a substrate temperature of 600° C. A composition analysis made on the thus obtained ferroelectric film by an induction coupling plasma (ICP) analysis revealed that the ferroelectric film had the composition of Bi (Al_{0.3},Ga_{0.7})O₃. Also, a crystal structure analysis made on the obtained film by an X-ray diffraction (XRD) analysis revealed that the film was a perovskite single-phase film.

Since Bi(Al_{0.3},Ga_{0.7})O₃ has the composition richer in Ga than Bi(Al_{0.5},Ga_{0.5})O₃, it is considered that the characteristics of Bi(Al_{0.3},Ga_{0.7})O₃ becomes close to the characteristics of BiGaO₃. As shown in Table 3 and Table 5, the value of P_{T}/P_{R} of BiAlO₃ is 1.83, and the value of P_{T}/P_{R} of Bi(Al_{0.5},Ga_{0.5})O₃ is approximately 1.65. Therefore, it is predicted that Bi(Al_{0.3}Ga_{0.7})O₃ having the composition approximately midway between BiAlO₃ and Bi (Al_{0.5}, Ga_{0.5})O₃ exhibits the P_{T}/P_{R} value falling within the range of 1.65 to 1.83. Also, it is predicted that Bi(Al_{0.3},Ga_{0.7})O₃ exhibits the c/a value falling within the range of 1.26 to 1.29. From the foregoing, it is considered that Bi(Al_{0.3},Ga_{0.7})O₃ is the ferroelectric oxide with which both the displacement due to the rotation of the polarization axis accompanying the phase transition and the displacement due to the large increase of the absolute value of the polarization intensity are obtained.

### Example 2

With respect to a ferroelectric oxide in which the A site element was Bi, Fe and Co were selected as the B site elements, and composition design for the MPB composition or the composition in the vicinity of the MPB composition was made. In this case, since BiCoO₃ and BiFeO₃ are the ferroelectric substances and are, at the same time, antiferromagnetic substances, energy varies even further due to a difference in spin direction of antiferromagnetism (G-type, C-type, or the like). Therefore, in Example 2, the calculation was made by the first-principles calculation utilizing the density functional method in the same manner as that in Example 1, except that both the crystal structures and the types of the spin directions of the antiferromagnetism were taken into consideration. The energy obtained by the calculation is listed in Table 6 shown below. The lattice constant is listed in Table 7 shown below. The spontaneous polarization density is listed in Table 8 shown below.

In Table 6, as in Table 1, the energy was represented in units of eV. The energy of the crystal structure was represented by the relative value with respect to the energy of the most stable crystal structure, which energy was taken as the reference value. As shown in Table 6, the most stable crystal structure of BiCoO₃ was the C-type antiferromagnetic tetragonal system (P4mm), and the most stable crystal structure of BiFeO₃ was the G-type antiferromagnetic rhombohedral system (R3c). Therefore, it was confirmed that BiCoO₃ and BiFeO₃ were capable of being selected as BiZO₃ (BiCO₃ and BiDO₃) having the characteristics such that the most stable crystal structures had different symmetry characteristics and different directions of polarization. With respect to each of bulk sintered bodies of the respective simple substances having been produced by a high-pressure synthetic technique, it has been confirmed that the antiferromagnetism and the crystal structure coinciding with the aforesaid calculation results are obtained.

Also, as shown in Table 7, in the cases of the tetragonal system, each of BiCoO₃ and BiFeO₃ had a high lattice constant ratio (c/a value≧1.008). As shown in Table 8, in the cases of the tetragonal system, each of BiCoO₃ and BiFeO₃ had a high spontaneous polarization density and had the P_{T}/P_{R} ratio sufficiently higher than 1.1 (the P_{T}/P_{R} ratio being the ratio of the spontaneous polarization density P_{T} of the tetragonal system to the spontaneous polarization density P_{R} of the rhombohedral system). Therefore, from Table 7, with respect to the composite oxide of BiCoO₃ and BiFeO₃, it was considered that the value of ΔP occurring between the stage before the occurrence of the electric field-induced phase transition and after the occurrence of the electric field-induced phase transition became large by virtue of the effect of the polarization rotation due to the phase transition and the effect of the large P_{T}/P_{R} ratio of the spontaneous polarization densities.

TABLE 6

| BiCoO₃ (eV) | BiFeO₃ (eV) |
|---|---|
| 0.248 (R3c C-type) | 0.223 (R 3̅c G-type) |
| 0.178 (R3c G-type) | 0.197 (R3m G-type) |
| 0.018 (P4mm G-type) | 0.138 (P4mm G-type) |
| 0.000 (P4mm C-type) | 0.079 (P4mm C-type) |
| | 0.065 (R3c C-type) |
| | 0.000 (R3c G-type) |

TABLE 7

| | | BiCoO₃ | BiFeO₃ |
|---|---|---|---|
| Tetragonal | a-axis (Å) | 3.65 | 3.67 |
| system (P4mm) | c/a | 1.26 | 1.27 |
| Rhombohedral | a-axis (Å) | 3.84 | 3.90 |
| system (R3c) | (aᵣ/\sqrt{2}) | | |
| | α (°) | 59.99 | 59.813 |

TABLE 8

| | BiCoO₃ | BiFeO₃ |
|---|---|---|
| | (C/m²) | (C/m²) |
| P_{T} (spontaneous | 1.73 | 1.54 |
| polarization density of | (P4mm) | (P4mm) |
| tetragonal system) | | |
| P_{R} (spontaneous | 0.90 | 0.92 |
| polarization density of | (R3c) | (R3c) |
| rhombohedral system) | | |
| P_{T}/P_{R} | 1.88 | 1.67 |
| Stable structure | P4mm | R3c |

Thereafter, the composition adjustment was made for Bi(Fe, Co)O₃ such that Formula (1) shown above might be satisfied. Firstly, with respect to Bi(Fe_{0.5},Cu_{0.5})O₃ in which Fe:Co=50:50, the calculation of the total energy by the first-principles calculation using the super cell was made. Also, the calculation of the spontaneous polarization density with the Berry phase was made. For the calculation, as for the super cell, with respect to each of the tetragonal system (P4mm), which was the most stable crystal structure of BiCoO₃, and the rhombohedral system (R3c), which was the most stable crystal structure of BiFeO₃, the energy calculation was made in the state of the C-type antiferromagnetism and the G-type antiferromagnetism.

The total energy obtained by the calculation and the lattice constant ratio in the tetragonal system are listed in Table 9 shown below. In Table 9, as in Table 1, the energy of the crystal structure was represented by the relative value with respect to the energy of the most stable crystal structure, which energy is taken as the reference value.

As shown in Table 9, as for Bi(Fe_{0.5},Co_{0.5})O₃, the most stable crystal structure was the C-type antiferromagnetic tetragonal system (P4mm), and the energy difference between the C-type antiferromagnetic rhombohedral system (R3c) and the C-type antiferromagnetic tetragonal system (P4mm) was equal to 0.017 eV. The energy difference was thus smaller than the energy difference (0.079) between the G-type antiferromagnetic rhombohedral system (R3c) and the C-type antiferromagnetic tetragonal system (P4mm) of BiFeO₃ shown in Table 6 and the energy difference (0.178) between the G-type antiferromagnetic rhombohedral system (R3c) and the C-type antiferromagnetic tetragonal system (P4mm) of BiCoO₃ shown in Table 6. It was thus indicated that, in cases where BiFeO₃ and BiCoO₃ varying in most stable crystal structure formed the composite oxide (the solid solution) together with each other, the energy difference between the tetragonal system and the rhombohedral system became small, and the phase transition with the electric field application became apt to occur.

Also, as shown in Table 9, as for Bi(Fe_{0.5},Co_{0.5}) O₃, the lattice constant ratio in the cases of the C-type antiferromagnetic tetragonal system (P4mm) was equal to 1.27 and was thus markedly higher than the range of c/a≧1.008. It was thus confirmed that, in cases where BiFeO₃ and BiCoO₃ formed the composite oxide (the solid solution) together with each other, by the utilization of the MPB, a large increase in lattice constant ratio was obtained, and the markedly large piezoelectric gain (the markedly large polarization response effect) might be expected.

Further, in Table 9, it is shown that, in the cases of the tetragonal system (P4mm), little change occurs with the lattice constant ratio due to the difference of the type of the antiferromagnetism. Therefore, it is considered that the state of the magnetism does not have a large influence on the piezoelectric response. Accordingly, it is considered that, in cases where there is a difference in C-type antiferromagnetism and G-type antiferromagnetism due to the difference in Co and Fe composition ratio, the influence upon the piezoelectric response is small.

TABLE 9

| Crystal structure | | Total energy |
|---|---|---|
| Bi(Fe_{0.5}Co_{0.5})O₃ | Magnetism structure | (eV) |
| R3c | C-type | 0.085 |
| R3c | G-type | 0.017 |
| P4mm (a = 3.67Å, | G-type | 0.005 |
| c/a = 1.25) | | |
| P4mm (a = 3.65Å, | C-type | 0.0 |
| c/a = 1.27) | | |

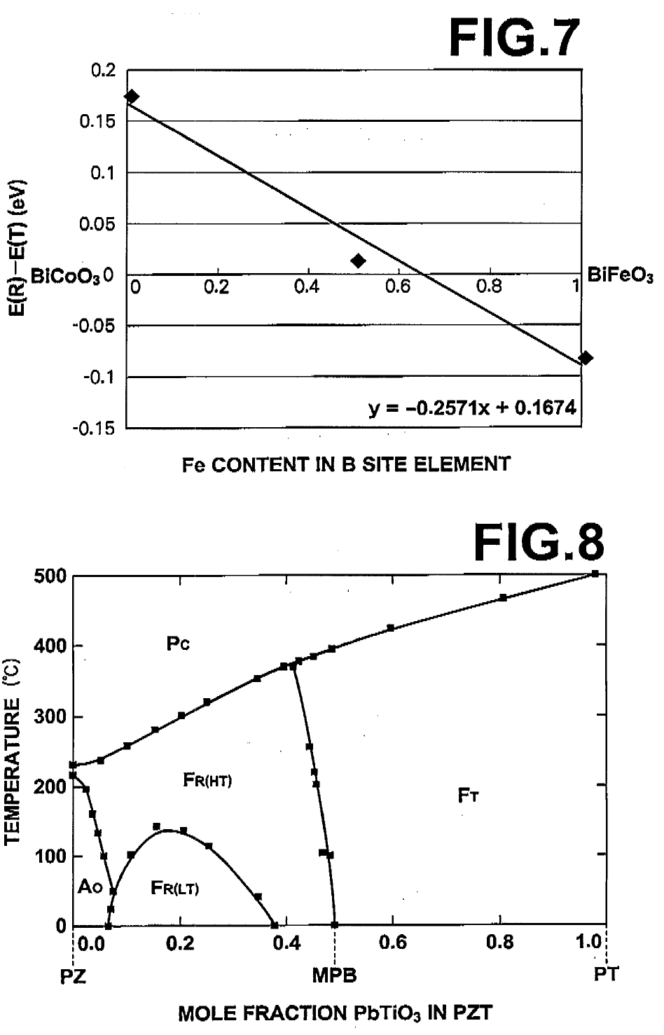

Thereafter, in the same manner as that in Example 1, the values of tetragonal system−rhombohedral system energy difference E(R)−E(T) were plotted with respect to the Fe and Co composition, and the calibration curve representing the relationship between the composition and E(R)−E(T) was formed (FIG. 7). With respect to the right side in Formula (1) shown above, the actuating electric field E was set at E=200 kV/cm, and the polarization intensity P was set at P=0.92 C/cm² (the value of BiFeO₃). Also, the calculation was made on the assumption that the system was the rhombohedral system, and that the polarization was directed toward the [111] direction and the electric field direction [001]. The energy units were converted into eV, and as a result a value of approximately 0.003 eV was obtained. From FIG. 7, it was found that the composition, in which the Fe:Co ratio fell within the range between 63:37 and 67:33, might be the composition capable of utilizing the structure phase transition induced by the electric field application. In the cases of a thin film or in cases where a small quantity of a dopant is introduced, the range of −8% from the minimum value to +8% from the maximum value may be taken into consideration, and it may be regarded that the composition, in which the Fe:Co ratio falls within the range between 55:45 and 75:25, might be the composition capable of utilizing the structure phase transition induced by the electric field application under the thin film conditions. Also, since the value of E(R)−E(T) is equal to approximately 0 in cases where the ratio of Fe:Co is in the vicinity of Fe:Co=65:35, it may be considered that the composition in which the ratio of Fe:Co is in the vicinity of Fe:Co=65:35 is the MPB composition.

Thereafter, a (100) SrTiO₃ substrate was prepared. An SrRuO₃ bottom electrode having a film thickness of 0.2 μm was formed on the surface of the substrate by the PLD method under the conditions of the substrate temperature of 650° C. A ferroelectric film having a film thickness of 200 nm was then formed by the PLD method by use of a target having a composition of Bi_{1.1}Fe_{0.65}CO_{0.35}O₃ under the conditions of a laser beam intensity of 300 mJ, a laser pulse frequency of 5 Hz, an oxygen partial pressure of 6.7 Pa, a substrate-target spacing distance of 50 mm, a target rotation speed of 9.7 rpm, and a substrate temperature of 600° C. A composition analysis made on the thus obtained ferroelectric film by an induction coupling plasma (ICP) analysis revealed that the ferroelectric film had the composition of Bi(Fe_{0.65},Co_{0.35})O₃. Also, a crystal structure analysis made on the obtained film by an X-ray diffraction (XRD) analysis revealed that the film was a perovskite single-phase film.

Since Bi(Fe_{0.65},Co_{0.35})O₃ has the composition slightly richer in Fe than Bi(Fe_{0.5},Co_{0.5})O₃, it is considered that the characteristics of Bi(Fe_{0.65},Co_{0.35})O₃ becomes slightly close to the characteristics of BiFeO₃. Also, it is predicted that Bi(Fe_{0.65},Co_{0.35})O₃ exhibits the c/a value in the vicinity of 1.27. From the foregoing, it is considered that Bi(Fe_{0.65},Co_{0.35})O₃ is the ferroelectric oxide with which both the displacement due to the rotation of the polarization axis accompanying the phase transition and the displacement due to the large increase of the absolute value of the polarization intensity are obtained.

### Referential Example 1

In order for the efficiency of the composition adjustment method in the process for producing a ferroelectric oxide in accordance with the present invention to be confirmed, as for PZT whose MPB composition was known, confirmation was made as to whether or not PZT having the MPB composition satisfied Formula (1).

It has been regarded that the MPB composition of PZT is the composition in the vicinity of Zr:Ti=52:48. Therefore, with respect to Pb(Zr_{0.5},Ti_{0.5})O₃, in which Zr:Ti=50:50 in the vicinity of the MPB composition, the calculation of the total energy by the first-principles calculation (under the conditions identical as those described above) using the super cell was made. Also, the calculation of the spontaneous polarization density with the Berry phase was made. In the cases of PZT, as for the super cell, there were employed a tetragonal system (14 mm) structure in which the B site atoms Zr and Ti were arrayed alternately in the [111] direction, a tetragonal system (P4mm) structure in which the B site atoms Zr and Ti were arrayed alternately in the [001] direction, and a rhombohedral system (R3m) structure in which the B site atoms Zr and Ti were arrayed alternately in the [111] direction.

The lattice constant ratio and the total energy obtained by the calculation are listed in Table 10 shown below. In Table 10, as in Table 1, the energy of the crystal structure was represented by the relative value with respect to the energy of the most stable crystal structure, which energy is taken as the reference value. As shown in Table 10, the energy difference between the tetragonal system 14 mm and the rhombohedral system R3m was equal to approximately 0.001 eV. Also, with respect to the right side in Formula (1) shown above, the actuating electric field E was set at E=100 kV/cm, and the polarization intensity P was set at P=0.71 C/cm² (the value of the rhombohedral system of PZT). Also, the calculation was made on the assumption that the electric field was directed toward the direction [001], and that the polarization was directed toward the [111] direction. The inner product of the electric field and the polarization intensity was thus calculated. Substitution of the volume (64 Å³) of the fundamental lattice of the crystal yielded the value of approximately 0.003 eV as the value of the right side of Formula (1) shown above. As described above, the energy difference between the rhombohedral system and the tetragonal system of PZT (Zr:Ti=50:50) was equal to approximately 0.001 ev and thus satisfied Formula (1) shown above. Actually, PZT (in the cases of the bulk crystal) has the MPB at Zr:Ti=52:48. The appropriateness of the composition adjustment method in accordance with the present invention was thus confirmed.

TABLE 10

| Crystal structure | Total energy |
|---|---|
| Pb(Zr_{0.5}Ti_{0.5})O₃ | (eV) |
| P4mm (c/a = 1.045) | 0.057 |
| I4mm (c/a = 1.035) | 0.001 |
| R3m (α = 89.55°) | 0.0 |

### (Evaluation)

In Example 1 and Example 2, the oxides forming the MPB are of the different kinds. However, as illustrated in FIG. 6 and FIG. 7, the calibration curves having good linearity were obtained. Therefore, it is considered that the composition adjustment method in the process for producing a ferroelectric oxide in accordance with the present invention is applicable regardless of the kind of the material.

Also, in Referential Example 1, the appropriateness of the values of the MPB composition obtained by the calculation has been confirmed. Therefore, the efficiency of the present invention has been confirmed. Also, from Example 1 and Example 2, it has been confirmed that the non-lead type ferroelectric oxide having the MPB composition or the composition in the vicinity of the MPB composition, which ferroelectric oxide has high piezoelectric performance, has been found out.

### INDUSTRIAL APPLICABILITY

The piezoelectric device in accordance with the present invention is capable of being utilized appropriately for piezoelectric actuators for use in ink jet type recording heads, magnetic recording and reproducing heads, micro electro-mechanical systems (MEMS) devices, micropumps, ultrasonic probes, and the like. The piezoelectric device in accordance with the present invention is also capable of being utilized appropriately for ferroelectric memories (FRAM's), and the like.

What is claimed is:

1. A process for producing a ferroelectric oxide having a composition that is represented by General Formula (a) shown below,
wherein the composition of the ferroelectric oxide is adjusted such that the most stable crystal structure X of the ferroelectric oxide that is represented by ACO₃ and the most stable crystal structure Y of the ferroelectric oxide that is represented by BDO₃ have different symmetry characteristics and different directions of polarization, and such that Formula (1) shown below is satisfied, and
the ferroelectric oxide having the thus adjusted composition is produced:
(Aₓ,B₁₋ₓ)(C_{y},D_{1-y})O₃ (a)
wherein x represents a number satisfying the condition of 0≦x≦1,
y represents a number satisfying the condition of 0≦y≦1,
each of A and B represents the A site element,
each of C and D represents the B site element,
O represents an oxygen atom,
each of A, B, C and D represents at least one kind of a metal element,
A and B may be of different compositions or may be of a common composition, with the proviso that, in cases where A and B are of the common composition, C and D are of different compositions, and
C and D may be of different compositions or may be of a common composition, with the proviso that, in cases where C and D are of the common composition, A and B are of different compositions,

|E(X)−E(Y)|≦E·PV (1)
wherein E(X) represents the energy of the ferroelectric oxide that is represented by General Formula (a) shown above at the time of the crystal structure X,
E(Y) represents the energy of the ferroelectric oxide that is represented by General Formula (a) shown above at the time of the crystal structure Y,
P represents the spontaneous polarization density vector at a stage before an electric field is applied,
E represents the actuating electric field vector,
V represents the volume of the fundamental lattice, and
E·P represents the inner product of E and P.

2. A process for producing a ferroelectric oxide as defined in claim 1 wherein the composition is adjusted such that Formula (2) or Formula (3) shown below is satisfied:

|Px/Py|>1.1 (2)

|Py/Px|>1.1 (3),
wherein Px represents the spontaneous polarization density of the ferroelectric oxide that is represented by General Formula (a) at the time of the crystal structure X, and
Py represents the spontaneous polarization density of the ferroelectric oxide that is represented by General Formula (a) at the time of the crystal structure Y.

3. A process for producing a ferroelectric oxide as defined in claim 1 wherein the crystal structure X or the crystal structure Y is of the tetragonal system, and
the composition is adjusted such that Formula (4) shown below is satisfied:
c/a≧1.008 (4)
wherein c represents the c-axis length in the crystal structure X or the crystal structure Y which is of the tetragonal system, and
a represents the a-axis length in the crystal structure X or the crystal structure Y which is of the tetragonal system.

4. A process for producing a ferroelectric oxide as defined in claim 1 wherein the actuating electric field vector E in Formula (1) satisfies the condition of 10<E (kV/cm)<500.

5. A process for producing a ferroelectric oxide as defined in claim 1 wherein either one of the A site and the B site in General Formula (a) contains a plurality of kinds of metal elements,
values of the difference E(X)−E(Y) are plotted with respect to the composition of the A site or the B site containing the plurality of kinds of the metal elements, which difference E(X)−E(Y) is the difference between the energy E(X) of the ferroelectric oxide that is represented by General Formula (a), the ferroelectric oxide having the composition of the A site or the B site containing the plurality of kinds of the metal elements, at the time of the crystal structure X, and the energy E(Y) of the ferroelectric oxide that is represented by General Formula (a), the ferroelectric oxide having the composition of the A site or the B site containing the plurality of kinds of the metal elements, at the time of the crystal structure Y,
a calibration curve, which represents the relationship between the composition of the A site or the B site containing the plurality of kinds of the metal elements and the difference E(X)−E(Y), is formed, and
the composition of the A site or the B site containing the plurality of kinds of the metal elements is adjusted by use of the calibration curve such that Formula (1) is satisfied.

6. A ferroelectric oxide, having a composition that is represented by General Formula (a) shown below (with the proviso that Pb(Zr,Ti)O₃ is excluded),
wherein the ferroelectric oxide has the composition such that the most stable crystal structure X of the ferroelectric oxide that is represented by ACO₃ and the most stable crystal structure Y of the ferroelectric oxide that is represented by BDO₃ have different symmetry characteristics and different directions of polarization, and such that Formula (1) shown below is satisfied:
(Aₓ,B₁₋ₓ)(C_{y},D_{1-y})O₃ (a)
wherein x represents a number satisfying the condition of 0≦x≦1,
y represents a number satisfying the condition of 0≦y≦1,
each of A and B represents the A site element,
each of C and D represents the B site element,
O represents an oxygen atom,
each of A, B, C and D represents at least one kind of a metal element,
A and B may be of different compositions or may be of a common composition, with the proviso that, in cases where A and B are of the common composition, C and D are of different compositions, and
C and D may be of different compositions or may be of a common composition, with the proviso that, in cases where C and D are of the common composition, A and B are of different compositions,

|E(X)−E(Y)|≦E·PV (1)
wherein E(X) represents the energy of the ferroelectric oxide that is represented by General Formula (a) shown above at the time of the crystal structure X,
E(Y) represents the energy of the ferroelectric oxide that is represented by General Formula (a) shown above at the time of the crystal structure Y,
P represents the spontaneous polarization density vector at a stage before an electric field is applied,
E represents the actuating electric field vector,
V represents the volume of the fundamental lattice, and
E·P represents the inner product of E and P.

7. A ferroelectric oxide as defined in claim 6 wherein a difference |M_{A}−M_{B}|, which is the difference between the mean atomic weight M_{A} of the A site element and the mean atomic weight M_{B} of the B site element, takes a value of at least 110.

8. A ferroelectric oxide as defined in claim 6 wherein the ferroelectric oxide has the composition such that Formula (2) or Formula (3) shown below is satisfied:

|Px/Py|>1.1 (2)

|Py/Px|>1.1 (3),
wherein Px represents the spontaneous polarization density of the ferroelectric oxide that is represented by General Formula (a) at the time of the crystal structure X, and
Py represents the spontaneous polarization density of the ferroelectric oxide that is represented by General Formula (a) at the time of the crystal structure Y.

9. A ferroelectric oxide as defined in claim 6 wherein the crystal structure X or the crystal structure Y is of the tetragonal system, and
the ferroelectric oxide has the composition such that Formula (4) shown below is satisfied:
c/a≧1.008 (4)
wherein c represents the c-axis length in the crystal structure X or the crystal structure Y which is of the tetragonal system, and
a represents the a-axis length in the crystal structure X or the crystal structure Y which is of the tetragonal system.

10. A ferroelectric oxide as defined in claim 6 wherein the A site element contains Bi.

11. A ferroelectric oxide as defined in claim 6 wherein the actuating electric field vector E in Formula (1) satisfies the condition of 10<E (kV/cm)<500.

12. A ferroelectric composition, containing a ferroelectric oxide as defined in claim 6.

13. A ferroelectric film, containing a ferroelectric composition as defined in claim 12.

14. A piezoelectric body, containing a ferroelectric oxide as defined in claim 6.

15. A piezoelectric body as defined in claim 14 wherein the piezoelectric body takes on the form of a piezoelectric film.

16. A piezoelectric device, comprising:
i) a piezoelectric body as defined in claim 14, and
ii) electrodes for applying an electric field across the piezoelectric body.
